(19) United States
(12) Patent Application Publication
(10) Pub. No.: US 2002/0093859 A1
(43) Pub. Date: Jul. 18, 2002

(54) Character processing method and apparatus and storage medium

(76) Inventor: Hiroyasu Kurashina, Malsumoto-shi (JP)

Correspondence Address: HOGAN & HARTSON L.L.P., 500 S. GRAND AVENUE, SUITE 1900, LOS ANGELES, CA, 90071-2611, US

(21) Appl. No.: 10/034,639

(22) Filed: Dec. 28, 2001

(30) Foreign Application Priority Data
Jan. 15, 2001 (JP) 2001-006186

(51) Int. Cl. G11C 7/00

(52) U.S. Cl. 365/200

(57) ABSTRACT

There are provided a character processing method and apparatus capable of editing and printing a plurality of texts, as desired, even by using a small-sized display screen, without reading/writing each text frequently, and a storage medium storing a program therefor. A matrix having elements of M (≧1) characters in one of row and column directions (X direction) by L (≧2) characters in the other (Y direction) is set as a text matrix. Text data of characters in the text matrix is stored in correlation with a position of each character in the text matrix. A partial matrix of the text matrix, which has elements of maximum N (1≦N≦M) by J (1≦J≦L) characters in the X and Y directions is set as a display matrix. Images of characters in the display matrix are displayed in correlation with a position of each character in the display matrix, based on the text data. An arbitrary k-th one, where k=1, 2, 3, . . . or L, of L partial matrices of the text matrix arranged in the Y direction each having one character in the Y direction and maximum M characters in the X direction is set as a k-th candidate processing matrix. One of the L candidate processing matrices is selected as a processing matrix, and characters in the processing matrix are determined as processing characters.

### BACKGROUND OF THE INVENTION

1. Field of the Invention

This invention relates to a character processing method and apparatus, and a storage medium storing a program therefor.

2. Prior Art

A personal computer or a word processor is capable of editing character strings (letter strings) each formed of one or more letters, symbols, numerals and/or figures (hereinafter typically referred to as “letters” or generically referred to as “characters”) entered as desired by a user, forming sentences (i.e. a document or text) desired by the user, and printing the same on a print medium as required. Therefore, the personal computer or the word processor having the functions of performing various kinds of processing on characters as described above is regarded as a kind of character processing apparatus. Further, the tape printing apparatus and the like are also known as small-sized apparatuses of the above-mentioned kind. More specifically, the tape printing apparatus is also capable of entering and editing character strings as desired, forming a desired text, and printing the same on a tape.

Conventionally, in the above type of character processing apparatus, a plurality of entered documents (texts) are each registered (stored) as a file (text file) or the like such that various kinds of processing including editing and printing can be performed on any text at any time, and a selected one of the documents or texts is read out, as required, and displayed on a processing screen (so-called edit screen) which is also called a text edit screen or the like. In this case, a text to be edited in response to user operations via a keyboard or the like is only one text currently displayed on the edit screen, and a text to be printed in response to an instruction for printing is also only one text currently displayed on the edit screen.

For this reason, in order to edit and/or print another text, it is required to read out the text from a file and display the same. Further, when the text currently displayed on the edit screen is being edited e.g. for modification or correction, it is required to re-register (save) the text in the file temporarily and then read out and display a next text. In short, for executing editing, printing, and so forth, it is required to read and write each text frequently. To meet the requirements, recent personal computers and the like are designed such that a plurality of edit screens corresponding respectively to texts different from each other can be displayed simultaneously. However, this method is applicable only to an apparatus, such as a personal computer, having a large-sized display screen, but not suitable for an apparatus, such as a tape printing apparatus, having a relatively small-sized display screen.

### SUMMARY OF THE INVENTION

It is an object of the invention to provide a character processing method and apparatus which is capable of carrying out editing, printing and/or other processes on a plurality of texts, as desired, even by using a small-sized display screen, without reading/writing each text frequently, and a storage medium storing a program therefor.

To attain the above object, according to a first aspect of the invention, there is provided a method of processing characters, comprising the steps of:

setting, as a text matrix, a matrix which is capable of having elements of M by L characters which are arbitrary at the maximum, where M represents a number of characters which can be arranged in an X direction as one of a row direction and a column direction in the matrix and is defined as an integer equal to or larger than 1 and L represents a number of characters which can be arranged in a Y direction as another of the row direction and the column direction and is defined as an integer equal to or larger than 2;

storing text data representative of each character contained in the text matrix in a manner correlated with a position of the character in the text matrix;

setting, as a display matrix, a partial matrix corresponding to a portion of the text matrix and capable of having elements of N by J characters at the maximum, where N represents a number of characters which can be arranged in the X direction and is defined as an integer satisfying the relationship of 1≦N≦M and J represents a number of characters which can be arranged in the Y direction and is defined as an integer satisfying the relationship of 1≦J≦L;

displaying an image of each character contained in the display matrix in a manner correlated with a position of the character in the display matrix, based on the text data of the character;

setting, as a k-th candidate processing matrix, an arbitrary k-th one, where k=1, 2, 3, . . . or L, of L partial matrices of the text matrix arranged in the Y direction as first to L-th candidate processing matrices each of which is capable of having one character in the Y direction and M characters at the maximum in the X direction; and

selecting one of the L candidate processing matrices as a processing matrix, and then determining characters contained in the processing matrix as processing characters.

To attain the above object, according to a second aspect of the invention, there is provided a character processing apparatus for processing characters, comprising:

text matrix-setting means for setting, as a text matrix, a matrix which is capable of having elements of M by L characters which are arbitrary at the maximum, where M represents a number of characters which can be arranged in an X direction as one of a row direction and a column direction in the matrix and is defined as an integer equal to or larger than 1 and L represents a number of characters which can be arranged in a Y direction as another of the row direction and the column direction and is defined as an integer equal to or larger than 2;

text data-storing means for storing text data representative of each character contained in the text matrix in a manner correlated with a position of the character in the text matrix;

display matrix-setting means for setting, as a display matrix, a partial matrix corresponding to a portion of the text matrix and capable of having elements of N by J characters at the maximum, where N represents a number of characters which can be arranged in the X direction and is defined as an integer satisfying the relationship of 1≦N≦M and J represents a number of characters which can be arranged in the Y direction and is defined as an integer satisfying the relationship of 1≦J≦L;

display means for displaying an image of each character contained in the display matrix in a manner correlated with a position of the character in the display matrix, based on the text data of the character;

candidate processing matrix-setting means for setting, as a k-th candidate processing matrix, an arbitrary k-th one, where k=1, 2, 3, . . . or L, of L partial matrices of the text matrix arranged in the Y direction as first to L-th candidate processing matrices each of which is capable of having one character in the Y direction and M characters at the maximum in the X direction; and

processing object-selecting means for selecting one of the L candidate processing matrices as a processing matrix, and then determining characters contained in the processing matrix as processing characters.

To attain the above object, according to a third aspect of the invention, there is provided a computer-readable storage medium storing a program for causing a computer to execute a method of processing characters, the program comprising:

a module for setting, as a text matrix, a matrix which is capable of having elements of M by L characters which are arbitrary at the maximum, where M represents a number of characters which can be arranged in an X direction as one of a row direction and a column direction in the matrix and is defined as an integer equal to or larger than 1 and L represents a number of characters which can be arranged in a Y direction as another of the row direction and the column direction and is defined as an integer equal to or larger than 2;

a module for storing text data representative of each character contained in the text matrix in a manner correlated with a position of the character in the text matrix;

a module for setting, as a display matrix, a partial matrix corresponding to a portion of the text matrix and capable of having elements of N by J characters at the maximum, where N represents a number of characters which can be arranged in the X direction and is defined as an integer satisfying the relationship of 1≦N≦M and J represents a number of characters which can be arranged in the Y direction and is defined as an integer satisfying the relationship of 1≦J≦L;

a module for displaying an image of each character contained in the display matrix in a manner correlated with a position of the character in the display matrix, based on the text data of the character;

a module for setting, as a k-th candidate processing matrix, an arbitrary k-th one, where k=1, 2, 3, . . . or L, of L partial matrices of the text matrix arranged in the Y direction as first to L-th candidate processing matrices each of which is capable of having one character in the Y direction and M characters at the maximum in the X direction; and

a module for selecting one of the L candidate processing matrices as a processing matrix, and then determining characters contained in the processing matrix as processing characters.

According to this character processing method and apparatus and storage medium, as a text matrix, there is set a matrix which is capable of having elements of M by L characters which are arbitrary at the maximum, where M represents a number of characters which can be arranged in an X direction as one of a row direction and a column direction in the matrix and is defined as an integer equal to or larger than 1 and L represents a number of characters which can be arranged in a Y direction as another of the row direction and the column direction and is defined as an integer equal to or larger than 2. Text data representative of each character contained in the text matrix is stored in a manner correlated with a position of the character in the text matrix. As a display matrix, there is set a partial matrix corresponding to a portion of the text matrix and capable of having elements of N by J characters at the maximum, where N represents a number of characters which can be arranged in the X direction and is defined as an integer satisfying the relationship of 1≦N≦M and J represents a number of characters which can be arranged in the Y direction and is defined as an integer satisfying the relationship of 1≦J≦L. An image of each character contained in the display matrix is displayed in a manner correlated with a position of the character in the display matrix, based on the text data of the character. As a k-th candidate processing matrix, there is set an arbitrary k-th one, where k=1, 2, 3, . . . or L, of L partial matrices of the text matrix arranged in the Y direction as first to L-th candidate processing matrices each of which is capable of having one character in the Y direction and M characters at the maximum in the X direction. One of the L candidate processing matrices is set as a processing matrix, and then characters contained in the processing matrix are determined as processing characters.

To sum up, assuming that M is an integer satisfying the relationship of M≧1, L an integer satisfying the relationship of L≧2, N an integer 1≦N≦M, J an integer 1≦J≦L, and K an integer 1≦K≦L, there are set a text matrix having elements of M (in the X direction) by L (in the Y direction) desired (text) characters at the maximum, a display matrix which is a partial matrix of the text matrix and having elements of N (in the X direction) by J (in the Y direction) characters at the maximum, and a k-th candidate processing matrix having elements of M (in the X direction)×1 (in the Y direction) characters at the maximum.

In the preset character processing method and apparatus, and storage medium, text data representative of each character in the text matrix is stored in a manner correlated with a position of the character in the text matrix, and images of the characters in the display matrix are displayed in a manner correlated with respective positions in the display matrix, based on text data of the characters in the display matrix. Then, one of the L candidate processing matrices ranging from the first candidate processing matrix to the L-th candidate processing matrix is selected as a processing matrix, and then each character contained in the processing matrix is determined as a processing character. As a result, by assigning different character groups (e.g. documents (texts)) to the respective L candidate processing matrices ranging from the first processing matrix to the L-th processing matrix, it is possible to select one of the candidate processing matrices as a processing matrix and determine a character group (e.g. a text) within the processing matrix as a processing object. Therefore, in this case, the characters in the text matrix are provided by the characters of a plurality of documents.

As a result, when any one of a plurality of documents (texts) is required to be selected as a processing object and subjected to various processes including editing and printing, the present character processing method and apparatus makes it possible to select the text for processing without carrying out any special operations for reading/writing the same or other texts. Further, in this case, it is not required to display the plurality of texts simultaneously, and hence a large-sized display screen is not needed. Thus, in this method and apparatus, it is possible to use the small-sized display screen and carry out editing, printing and/or other processes on a plurality of texts as desired without reading/writing each text frequently. It should be noted that the above processing matrix can also be selected e.g. by inputting the number k of a desired k-th processing candidate as a numerical value.

It is preferred that the method according to the first aspect further comprises the step of shifting a position of the display matrix in the text matrix.

Similarly, it is preferred that the character processing apparatus according to the second aspect further comprises display matrix-shifting means for shifting a position of the display matrix in the text matrix.

According to these preferred embodiment, since the position of the display matrix in the text matrix can be shifted, the user can cause each portion of the text matrix to be displayed for confirmation of stored text data. Also, in an edit process or the like, the user can view and check the result of the process (editing).

More preferably, in the first and second aspects of the invention, the processing matrix is selected from J candidate processing matrices of the L candidate processing matrices, each of the J candidate processing matrices having at least part thereof overlapping the display matrix.

According to this preferred embodiment of each aspect of the invention, since the processing matrix can be selected from the J candidate processing matrices of the L candidate processing matrices, each of the J candidate processing matrices having at least part thereof overlapping the display matrix, it is possible to select the processing matrix as a processing object after viewing and recognizing at least the portion of the same displayed on the display screen. Further, since the processed data is displayed, it is easy to confirm or check the result of an edit process or the like.

Further preferably, in the first and second aspects of the invention, the processing matrix is in a predetermined position in sequence of the J candidate processing matrices.

According to this preferred embodiment of each aspect of the invention, the processing matrix is in a predetermined position in sequence of the J candidate processing matrices. This means that even when display of the J candidate processing matrices changes with a shift of the position of the display matrix, a candidate processing matrix which can be selected as a processing object is always in the predetermined position in sequence of the J candidate processing matrices, and hence the processing object can be automatically set by shifting the position of the display matrix. In other words, it is possible to select a processing matrix by shifting the position of the display matrix.

It is preferred that the method according to the first aspect of the invention further comprises the step of editing the text data of the processing characters by addition, deletion or modification.

Similarly, it is preferred that the character processing apparatus according to the second aspect of the invention further comprises edit means for editing the text data of the processing characters by addition, deletion or modification.

According to these preferred embodiment, it is possible to add, delete or modify text data of processing characters, to thereby edit characters in the text matrix.

Preferably, in the first and second aspects of the invention, the characters in the text matrix include characters forming at least one character string, the k-th candidate processing matrix has one or more character strings arranged in the X direction.

According to this preferred embodiment of each aspect of the invention, the characters in the text matrix include characters forming at least one character string, and one or more character strings are arranged in the X direction in the k-th candidate processing matrix. More specifically, characters arranged as elements in the X direction in the text matrix form not a group (character group) of characters arranged at random but a character string. Further, one or more character strings, i.e. character groups which can form a document (text) are arranged in the X direction in the k-th candidate processing matrix, so that by assigning different character groups (e.g. texts) to the respective L candidate processing matrices, it is possible to select one of the candidate processing matrices as a processing object to thereby determine the text within the processing matrix, as the processing object.

More preferably, in the first and second aspects of the invention, the characters in the text matrix include at least one attribute character accompanying the characters forming the at least one character string, the at least one attribute character indicating at least one of an attribute of each character string and an attribute of the characters forming the each character string.

According to this preferred embodiment of each aspect of the invention, since the characters in the text matrix include at least one attribute character accompanying the characters forming the at least one character string, the at least one attribute character indicating at least one of an attribute of each character string and an attribute of the characters forming the each character string, this attribute character holds attribute information of each character string or each character. In this case, the attribute character can be handled similarly to the other characters, and hence the attribute character is easy to handle. Further, since the character string is displayed together with its attribute information, the user can easily understand the attribute information of each character string.

More preferably, in the first and second aspects of the invention, the attribute character includes a position information character indicative of at least one of a line number, a paragraph number and a document number of the at least one character string.

According to this preferred embodiment of each aspect of the invention, since each attribute character includes a position information character indicative of at least one of a line number, a paragraph number and a document number of a character string, the attribute character holds position information of each character string. In this case, the attribute character can be handled similarly to the other characters, so that it is possible not only to handle the attribute character easily, but also to display each character string together with the attribute information, which makes it easy for the user to obtain position information of a currently displayed character string, i.e. to recognize the positions of a document, a paragraph, and a line of the displayed character string in respective sequences of documents, paragraphs, and lines.

More preferably, the step of storing text data includes the step of storing format information of each character string to be laid out.

More preferably, the text data-storing means includes means for storing format information of each character string to be laid out.

According to these preferred embodiments, format data is stored which determines a so-called format, including so-called type family data, e.g. data of a typeface, such as Courier New or Times New Roman, for use in printing each character (image), style data indicative of so-called character styles, such as italic and outline, and various mode data including information of decoration, such as highlight and half tone dot meshing. Therefore, it is possible to elaborate text data into various forms and/or to print a print image in a manner reflecting the designs of the text data.

It is preferred that the method according to the first aspect further comprises the step of printing at least part of an image of the processing characters on a print medium, based on the text data of the processing characters.

It is similarly preferred that the character processing apparatus according to the second aspect further comprises printing means for printing at least part of an image of the processing characters on a print medium, based on the text data of the processing characters.

According to these preferred embodiments, it is possible to print at least part of an image of processing characters based on text data of the characters. It should be noted that when processing characters include attribute characters as described above, the attribute characters are not printed, but character strings accompanied by the respective attribute characters can be printed (e.g. in a paragraph or on a line designated by an attribute character) based on the attribute characters.

Preferably, the print medium is a tape.

According to this preferred embodiment of each aspect of the invention, since the print medium is a tape, the method and apparatus of the present invention can be applied to a tape printing apparatus.

The above and other objects, features, and advantages of the invention will become more apparent from the following detailed description taken in conjunction with the accompanying drawings.

### BRIEF DESCRIPTION OF THE DRAWINGS

FIG. 1 is a perspective view of a tape printing apparatus to which is applied a character processing method and apparatus according to an embodiment of the invention;

FIG. 2 is a perspective view of the FIG. 1 tape printing apparatus with its lid open;

FIG. 3 is a block diagram of a control system of the FIG. 1 tape printing apparatus;

FIG. 4 is a flowchart showing a conceptual representation of an overall control process executed by the FIG. 1 tape printing apparatus;

FIGS. 5A to 5F are views useful in explaining examples of print images;

FIG. 6 is a diagram useful in explaining images of each text registered (stored) as a text file according to a conventional character processing method employed for text management;

FIG. 7 is a diagram useful in explaining images of a text matrix and a text edit area;

FIG. 8 is a diagram useful in explaining an image of text data read into a text edit area from a text file according to a conventional character processing method employed for text management;

FIG. 9 is a diagram useful in explaining images of a display matrix and a text display area in the FIG. 8 case;

FIG. 10 is a diagram similar to FIG. 9, which shows another example;

FIG. 11 is a diagram representing an image of an example of the relationship between a text edit area, a text display area, and a file area, according to a conventional character processing method employed for text management;

FIG. 12 is a diagram representing an image of an example of the relationship between a text matrix and a text edit area, and a k-th candidate processing matrix and a k-th candidate processing area;

FIG. 13 is a diagram showing an image of a state of each k-th candidate processing matrix being stored in a corresponding k-th candidate processing area, in the case of FIG. 12 example;

FIG. 14 is a diagram similar to FIG. 13, which shows another example;

FIG. 15 is a diagram similar to FIG. 13, which shows still another example;

FIG. 16 is a diagram showing a simplified form of FIG. 15;

FIG. 17 is a diagram representing an image of an example of the relationship between a text edit area and a text display area, in the case of the FIG. 16 example;

FIG. 18 is a diagram similar to FIG. 17, which shows another example;

FIG. 19 is a diagram representing an image of an example of the relationship between a text edit area, a text display area, and a k-th candidate processing area;

FIG. 20 is a diagram similar to FIG. 16, which shows another example;

FIGS. 21A and 21B are diagrams useful in explaining examples of operations shown in FIG. 22 et seq., in which:

FIG. 21A shows examples of notations of document numbers; and

FIG. 21B illustrates a format of the display;

FIG. 22 is a diagram useful in explaining examples of operations for shifting the positions of a text display area and a display matrix within a text edit area and a text matrix, respectively;

FIG. 23 is a continuation of FIG. 22;

FIG. 24 is a diagram useful in explaining examples of operations for editing and printing;

FIG. 25 is a continuation of FIG. 24; and

FIG. 26 is a continuation of FIG. 25.

### DETAILED DESCRIPTION OF PREFERRED EMBODIMENT

The invention will now be described in detail with reference to the drawings showing an embodiment thereof. In the embodiment, a character processing method and apparatus according to the invention is applied to a tape printing apparatus.

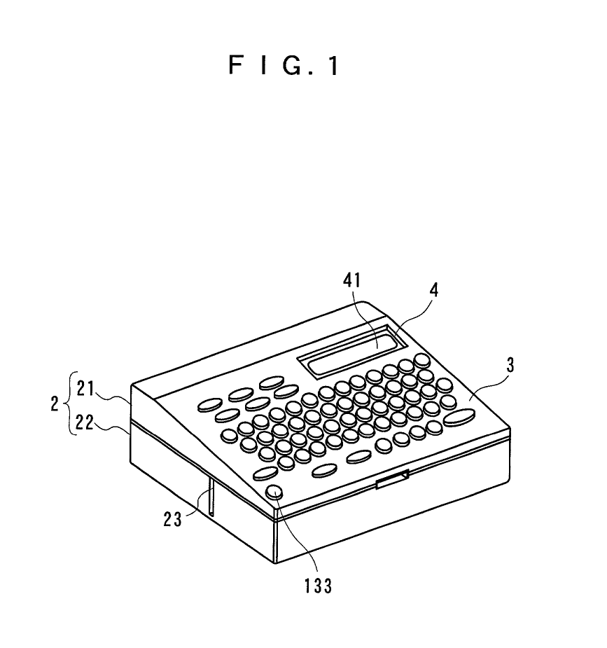

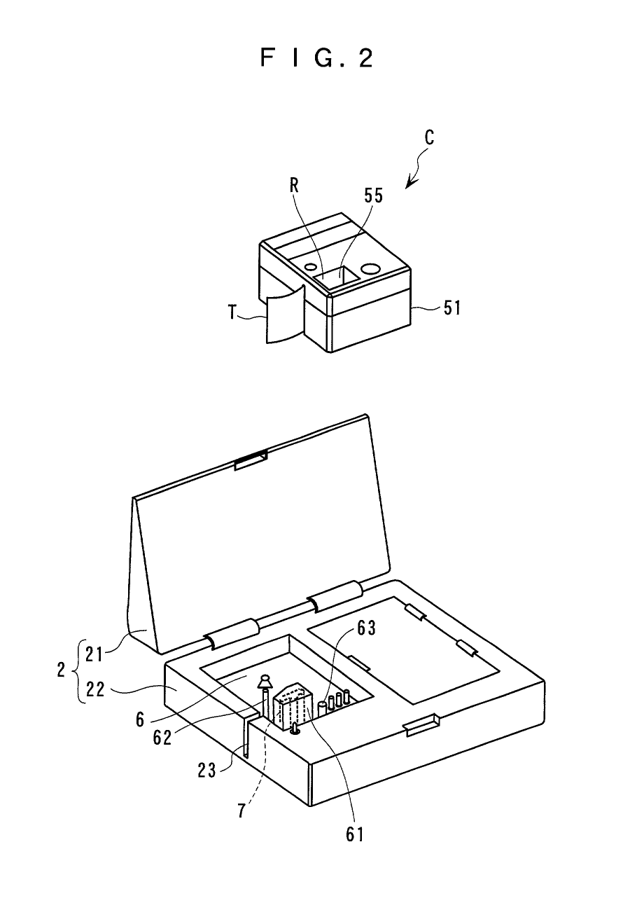

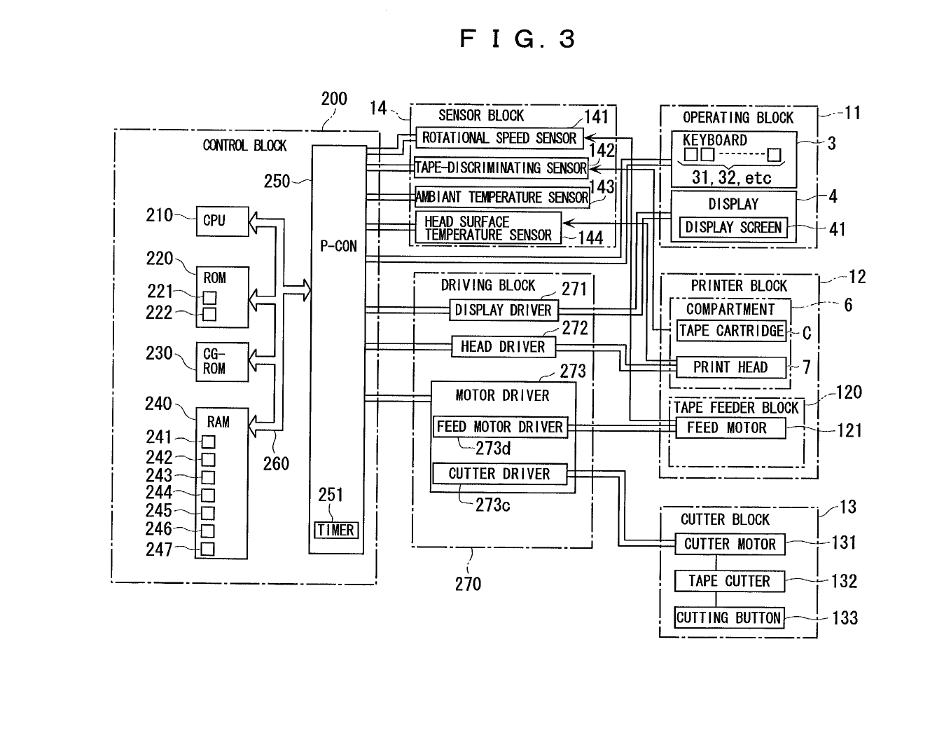

FIG. 1 shows the appearance of the whole tape printing apparatus according to the present embodiment, while FIG. 2 shows the tape printing apparatus with a lid thereof open. Further, FIG. 3 shows a control system of the tape printing apparatus.

As shown in FIGS. 1 and 2, the tape printing apparatus 1 includes a casing 2 divided into an upper casing (lid) 21 and a lower casing 22 and forms an outer shell of the apparatus. The upper casing 21 has a keyboard 3 and a display 4 arranged thereon, while the lower casing 22 has various mechanisms, including a compartment 6, arranged therein.

Further, as shown in FIG. 3, the tape printing apparatus 1 is basically comprised of an operating block 11 having the keyboard 3 and the display 4 for interfacing with the user, a printer block 12 having a print head (thermal head) 7 and a tape feeder block 120 for printing on a printing tape(hereinafter simply referred to as “the tape”) T unwound from a tape cartridge C mounted in the compartment 6, a cutter block 13 for cutting off a printed portion of the tape T, a sensor block 14 having various sensors for carrying out various detecting operations, a driving block 270 having drivers for driving circuits of devices of the apparatus 1, and a control block 200 for controlling operations of blocks and devices of the apparatus 1 including the above-mentioned sensors and drivers. To implement the above construction, the casing 2 accommodates not only the above-mentioned blocks including the printer block 12, the cutter block 13, and the sensor block 14, but also a circuit board, not shown. On the circuit board are mounted a power supply unit, the circuits of the driving block 270 and the control block 200, etc. The power supply unit is connected to a connector port for connecting an AC adapter thereto, and batteries, such as nicad batteries, which can be removably mounted within the casing 2 from outside.

In the tape printing apparatus 1, after mounting the tape cartridge C in the compartment 6, the user enters printing information, such as desired characters (letters, numerals, symbols, simple figures, etc.) via the keyboard 3, while confirming or viewing the results of the entry or edit of the printing information on the display 4. Thereafter, when the user instructs the apparatus 1 to perform a printing operation via the keyboard 3, the tape feeder block 120 unwinds a tape T from the tape cartridge C, while the print head 7 prints on the tape T. The printed portion of the tape T is delivered from a tape exit 22 as the printing proceeds. When the printing is completed as desired, the tape feeder block 120 further advances the tape T until an end of a tape length (the length of a label to be formed) including the length of margins comes to a cutting position, and then stops the feeding of the tape.

As shown in FIGS. 2 and 3, the printer block 12 has the compartment 6 arranged under the lid 21 for mounting the tape cartridge C therein. The tape cartridge C can be mounted in or removed from the compartment 6 when the lid 21 is open. The tape cartridge C has a cartridge casing 51 holding a tape T having a predetermined width (within a range of approximately 4.5 to 48 mm) and an ink ribbon R. The tape cartridge C is formed with a through hole 55 for receiving therein a head unit 61 arranged in the compartment 6. Further, the tape cartridge C has a plurality of small holes formed in the bottom thereof for discrimination of a type of the tape T contained therein from the other types of the tape T having different widths, which are contained in other types of tape cartridges C. The compartment 6 has a tape-discriminating sensor 142 comprised of micro-switches or the like, for detecting the above holes to thereby determine the type of the tape T set for use or arbitrary setting information.

The tape T has an adhesive surface formed on the reverse side thereof, with a peel-off paper layer covering the adhesive surface. The tape T and the ink ribbon R are fed or run such that they pass by the through hole 55, in a state overlaid upon each other, and the tape T alone is delivered out of the tape cartridge C, but the ink ribbon R is taken up into a roll within the tape cartridge C.

The head unit 61 contains the print head 7 implemented by a thermal head. The print head 7 is brought into contact with the reverse side of the ink ribbon R exposed to the through hole 55 of the tape cartridge C when the tape cartridge C is mounted in the compartment 6 with the print head 7 fitted in the through hole 55. Then, by driving the print head 7 while heating the same, desired letters and the like are printed on the surface of the tape T. Further, in the compartment 6, there are arranged an ambient temperature sensor 143, such as a thermistor, for detecting the ambient temperature (temperature of the environment), and supplying a signal indicative of the detected ambient temperature to the control block 200.

Further, the casing 2 (lower casing 22) has a left side portion thereof formed with the tape exit 23 for communication between the compartment 6 and the outside of the apparatus. Opposed to the tape exit 22, there is arranged a tape cutter 132 for cutting off a delivered or dispensed portion of the tape T.

Further, the compartment 6 is provided with drive shafts 62, 63 for engagement with driven portions of the tape cartridge 4 mounted in the compartment 6. A feed motor 121 as a drive source drives these drive shafts 62, 63 for rotation to feed or advance the tape T and the ink ribbon R in the tape cartridge C, and at the same time the print head 7 is driven in synchronism with the feeding of the tape and ribbon to carry out printing. Further, after completion of the printing operation, the tape T continues to be fed to bring a predetermined cutting position (corresponding to the tape length) on the tape T to the position of the tape cutter 132.

It should be noted that there is arranged a head surface temperature sensor 144, such as a thermistor, in intimate contact with the surface of the print head 7, for detecting the temperature of the surface of the print head 7 and supplying a signal indicative of the detected head surface temperature to the control block 200. Further, the feed motor 121 has an end on which is rigidly fitted a disc, not shown, formed with detection openings, and a rotational speed sensor 141 comprised of a photo sensor or the like is provided to face the path of the detection openings of the disc, for sending information of the rotational speed of the feed motor 121 detected thereby to the control block 200.

The cutter block 13 includes a tape cutter 132, a cutting button 133 for being manually operated to cause the tape cutter 132 to cut the tape T when a desired length printing is carried out, for instance, and a cutter motor 131 for automatically driving the tape cutter 132 to cut the tape T when a fixed length printing is carried out, for instance. To selectively carry out one of the two cutting operations, the tape printing apparatus 1 is capable of being switched between a manual cutting mode and an automatic cutting mode by a mode-setting operation. More specifically, in the manual cutting mode, when the printing operation is completed, the user pushes the cutting button 133 arranged on the casing 2, whereby the tape cutter 132 is actuated to cut the tape T to a desired length. On the other hand, in the automatic cutting mode, after completion of the printing operation, the tape T is sent further by the length of a rear margin, and then stopped, whereupon the cutter motor 131 is driven to cut off the tape T.

The sensor block 14 includes the rotational speed sensor 141, the tape-discriminating sensor 142, the ambient temperature sensor 143, the head surface temperature sensor 144. It should be noted that the above sensors can be omitted to suit the actual requirements of the tape printing apparatus.

The driving block 270 includes a display driver 271, a head driver 272, and a motor driver 273. The display driver 271 drives the display 4 of the operating block 11 in response to control signals delivered from the control block 200, i.e. in accordance with commands carried by the signals. Similarly, the head driver 272 drives the print head 7 of the printer block 12 in accordance with commands from the control block 200. Further, the motor driver 273 includes a feed motor driver 273d for driving the feed motor 121 of the printer block 12, and a cutter motor driver 273c for driving the cutter motor 131 of the cutter block 13, and similarly to the display driver 271 and the head driver 272, drives each motor in accordance with commands from the control block 200.

The operating block 11 includes the keyboard 3 and the display 4. The display 4 has a display screen 41 which is capable of displaying desired letters, numerals, symbols, figures, etc. (hereinafter typically referred to as “letters” or generically referred to as “characters”) by six letters (or six characters) in full size (em-size) in the horizontal direction (X direction). The display 4 is used by the user e.g. to select character string data for processing or enter data and commands or instructions via the keyboard 3 to form character string data and edit the same, and view the resulting data.

On the keyboard 3, there are arranged a character key group 31 including an alphabet key group, a symbol key group, a number key group, and a nonstandard character key group for calling nonstandard characters for selection, as well as a function key group 32 for designating various operation modes. In a type of apparatus which is capable of entering the Japanese language, the character key group 31 includes a kana key group for entering Japanese hiragana letters and Japanese katakana letters, as well.

The function key group 32 includes a power key, not shown, a print key 322 for giving an instruction for a printing operation, a selection key, not shown, for finally determining entry of character data and starting a new line during text entry as well as determining selection of one of modes on a selection screen, a decoration-setting key, not shown, for setting a desired one of decoration forms including so-called character decoration by shading, underlining, enclosing, etc. and decoration using background patterns (including a ground pattern, an illustration, etc.), a color-setting key, not shown, for setting colors (including gradation, chromaticity, glossiness, transparency) of characters, backgrounds and decorations, and four cursor keys 330 (330U (up arrow key), 330D (down arrow key), 330L (left arrow key), 330R(right arrow key)) for moving the cursor or the display range of display image data on the display screen 41 in respective upward, downward, leftward, and rightward directions.

The function key group 32 also includes a cancel key, not shown, for canceling instructions, a shift key, not shown, for use in changing roles of respective keys as well as in modifying registered image data, an image key, not shown, for alternately switching between a text entry screen or a selection screen and a display screen (image screen) for displaying print image data, a proportion-changing (zoom) key, not shown, for changing a proportion between the size of print image data and the size of display image data displayed on the image screen, and a form key, not shown, for setting various forms including fonts and typefaces of letters.

Of course, similarly to keyboards of the general type, the above key entries may be made by separate keys exclusively provided therefor or by a smaller number of keys operated in combination with the shift key or the like. Here, for purposes of ease of understanding, the following description will be given assuming that there are provided as many keys as described above. As shown in FIG. 3, from the keyboard 3, various commands described above and data are input to the control block 200.

The control block 200 includes a CPU 210, a ROM 220, a character generator ROM (CG-ROM) 230, a RAM 240, a peripheral control circuit (P-CON) 250, all of which are connected to each other by an internal bus 260. The ROM 220 has a control program area 221 for storing control programs executed by the CPU 210 as well as a control data area 222 for storing control data including a color conversion table, and a character modification table. The CG-ROM 230 stores bit map data, i.e. data defining symbols, figures and the like, provided for the tape printing apparatus 1. When code data for identifying a character or the like is input thereto, it outputs the corresponding bit map data.

The RAM 240 is supplied with power by a backup circuit, not shown, such that stored data can be preserved even after the power is turned off by operating the power key. The RAM 240 includes areas of a register group 241, a character data area 242 for storing character data of letters or the like input by the user via the keyboard 3, a display image data area 243 for storing image data for display on the display screen 41, a print image data area 244 for storing print image data, a registered image data area 245 for storing registered image data, as well as a print record data area 246 and conversion buffer areas 247 including a color conversion buffer. The RAM 240 is used as a work area for carrying out the control process.

The P-CON 250 incorporates logic circuits for complementing the functions of the CPU 210 and handling interface signals for interfacing between the CPU 210 and peripheral circuits. The logic circuits are implemented by gate arrays, a custom LSI and the like. For instance, a timer 251 is also incorporated in the P-CON 250 for the function of measuring elapsed time. To perform its functions, the P-CON 250 is connected to the sensors of the sensor block 14 and the keyboard 3, for receiving the above-mentioned signals generated by the sensor block 14 as well as commands and data input via the keyboard 3, and inputting these to the internal bus 260 directly or after processing them. Further, the P-CON 250 cooperates with the CPU 210 to output data and control signals input to the internal bus 260 by the CPU 210 or the like, to the driving block 270 directly or after processing them.

The CPU 210 of the control block 200 receives the signals from the sensor block 14, and the commands and data input via the keyboard 3 via the P-CON 250, according to the control program read from the ROM 220, processes font data from the CG-ROM 230 and various data stored in the RAM 240, and delivers control signals to the driving block 270 via the P-CON 250 to thereby carry out position control during printing operations, display control of the display screen 41, and printing control of the print head 7 to carry out printing on the tape T under predetermined printing conditions. In short, the CPU 210 controls the overall operation of the tape printing apparatus 1.

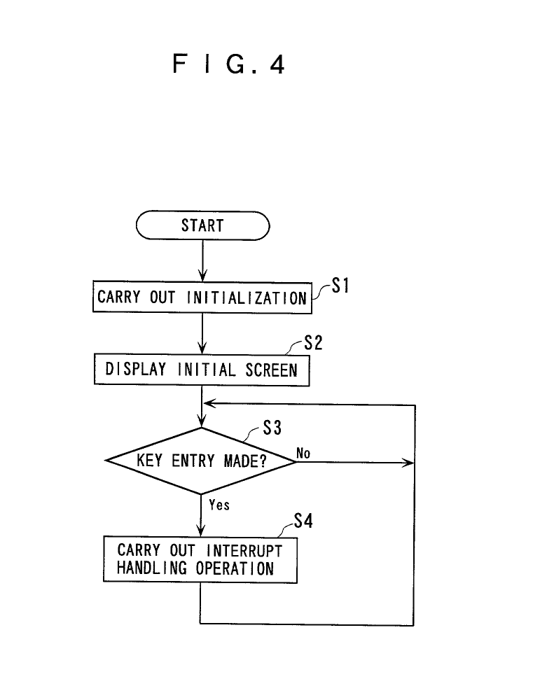

Next, the overall control process carried out by the tape printing apparatus 1 will be described with reference to FIG. 4. As shown in the figure, when the program for carrying out the control process is started e.g. when the power of the tape printing apparatus 1 is turned on, first, in a step S1, initialization of the system including restoration of saved control flags is carried out to restore the tape printing apparatus 1 to the state it was in before the power was turned off the last time. Then, the image that was displayed on the display screen 41 before the power was turned off the last time is shown as the initial screen in a step S2. The following steps in FIG. 4, that is, a step S3 for determining whether or not a key entry has been made and a step S4 for carrying out an interrupt handling operation are conceptual representations of actual operations. Actually, when the initial screen has been displayed in the step S2, the tape printing apparatus 1 enables an interrupt by key entry (keyboard interrupt), and maintains the key entry wait state (No to S3) until a keyboard interrupt is generated. When the keyboard interrupt is generated (Yes to S3), a corresponding interrupt handling routine is executed in the step S4, and after the interrupt handling routine is terminated, the key entry wait state is again enabled and maintained (No to S3).

Next, the principles of the character processing method according to the present embodiment will be described. In the character processing method, documents (texts) are managed such that editing and printing can be carried out on a text-by-text basis. Therefore, the character processing method can also be applied (or referred to) as a text managing method.

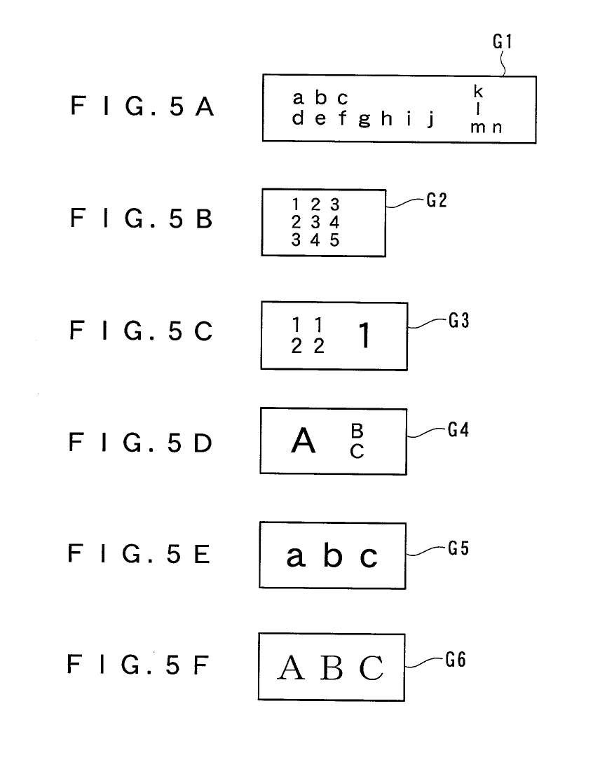

First, it is assumed here that a print image G1 of a document (text) formed of letter strings (character strings), including “abc” and “defghij” on respective first and second lines of a first paragraph, and “k”, “l” and “mn” on respective first, second and third lines of a second paragraph, as shown in FIG. 5A, is to be printed on a tape (print medium) T. In this case, it is required to prepare print image data representative of the print image G1.

In a process of forming the print image data, character images, such as “a”, “b” and “c” of the character string “abc”, are each stored at a predetermined location within the print image data area 244 and in a predetermined character size. Each character image is obtained by fetching corresponding font data, such as a dot map and an outline font, from the CG-ROM 230 (or another memory area (within the ROM 220 and the RAM 240) in which the character image was registered in advance by nonstandard character registration and the like) based on code data representative of the character, and generating image data from the fetched font data. This kind of data necessary for forming print image data is hereinafter referred to as “text data”.

In the present embodiment, text data includes data of a character size of each character (image). Each character size can be not only preset manually by the user, but also preset automatically according to the detected tape width of a tape T as a print medium and the number of lines forming each paragraph. Further, character sizes may be selectively set according to modes and the like. In the following, for simplicity and for purposes of ease of understanding, description will be given assuming that each character size is automatically set according to the width of a tape and the number of lines. For instance, examples of print images shown in FIGS. 5A to 5F are each formed based on one or more character sizes set automatically. In FIG. 5A, since the first paragraph is formed of two lines, the characters “abc” and the others in the paragraph are set to a character size for use in forming two lines according to the tape width. Further, in the figure, since the second paragraph is formed of three lines, the characters “k” and the others in the paragraph are set to a character size for use in forming three lines according to the tape width.

In addition, the text data includes format data for determining a so-called format. The format data includes so-called type family data, including data of a typeface, such as Courier New typeface or Times New Roman typeface, for use in printing each character (image), and style data indicative of so-called character styles, such as italic and outline, as well as various mode data including information of decoration, such as highlight and half tone dot meshing. The format data can be changed in an edit process. Further, based on the text data elaborately designed as above, it is possible to print a print image in a manner reflecting the designs of the text data, though in the following, detailed description thereof is omitted. Further, to generate the print image data, more specifically to print the print image G1, in the present example, it goes without saying that the text data includes code data representative of each of the character images “a”, “b” and “c” of the character string “abc”.

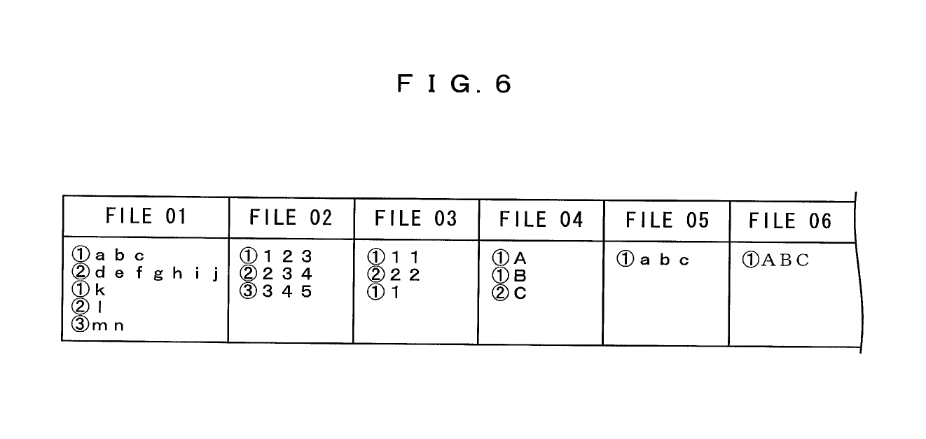

In the following description of the present embodiment, each line of a paragraph is designated by a circled number indicative of the line number thereof. More specifically, as shown in FIG. 6, circled number 1 is added to the first line of each paragraph, circled number 2 to the second line, and so forth. The addition of attribute characters (such as circled number 1) indicative of attributes of the above kind may be effected only for the present description, and actually, another method may be employed for adding information of the attributes (line numbers in the present case) to text data. However, in the present embodiment, each of the attribute characters is actually added immediately before a corresponding one of the character strings (e.g. “abc”). In this case, each attribute character (e.g. circled number 1) holds attribute information of a corresponding character string. The use of attribute characters makes it possible to handle attribute information, similarly to the other characters, and hence makes it easy to handle the same. Further, since each character string is displayed together with its attribute information, the user can easily understand the attribute information added to the character string.

In the case of the FIG. 5A print image, for instance, character strings “circled number 1 abc” and “circled number 2 defghij” indicate, respectively, that the first line of the first paragraph is formed by “abc” and that the second line is formed by “defghij”. Further, a character string “circled number 1 k” having another circled number 1 added thereto indicates that the first line of the following paragraph (second paragraph) is formed by “k”, and similarly, character strings “circled number 2 l” and “circled number 3 mn” indicate that the second line of the second paragraph is formed by “l” and that the third line is formed by “mn”. Accordingly, the user can readily image by these character strings having the respective attribute characters (by viewing them displayed on the display screen 41) that the print image G1 will be printed on a tape.

In the following, first, a conventional method of handling text data formed as above, or a so-called text managing method according to the prior art, will be described, and then the method of the present embodiment will be described.

In the conventional method, for instance, in order to provide the six kinds of print images G1 to G6 shown in FIGS. 5A to 5F such that each of them can be printed at a desired time point, a plurality of documents (texts) are entered and then registered (i.e. stored as entries to a predetermined database or catalog) e.g. as Files (text files) 01 to 06, as shown in FIG. 6, such that processes including editing and printing can be executed on each of the texts at any time. Then, a selected one of them is read out, as required, and displayed on a processing screen (so-called edit screen) referred to as a text edit screen or the like.

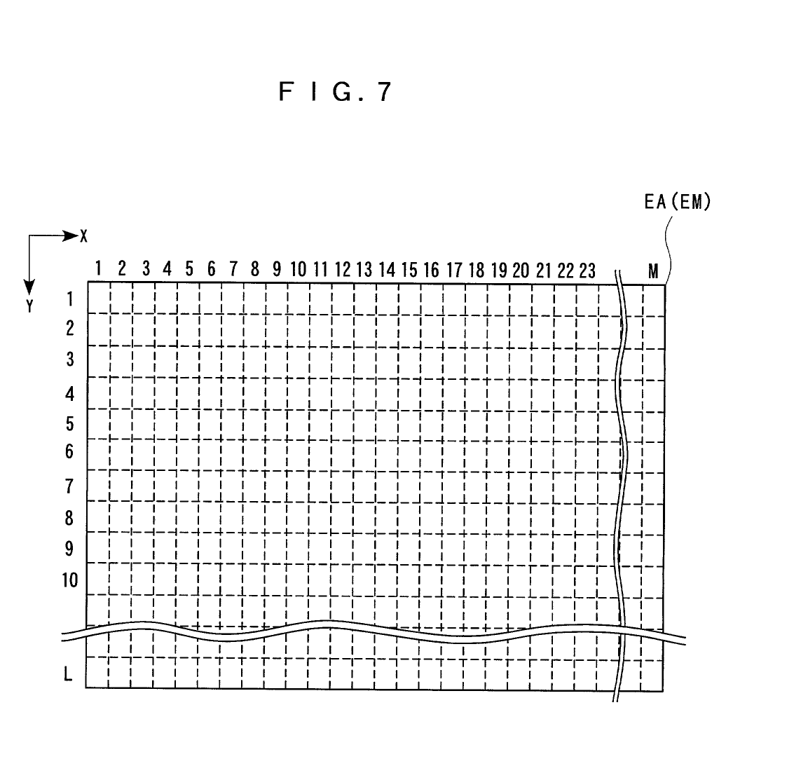

Now, a matrix EM shown in FIG. 7 is considered by way of an example for purposes of easy comparison with the text managing (character processing) method of the present embodiment, described in detail hereinafter. The matrix EM has one of the row and column directions thereof (the row direction in this example) defined as an X direction, and the other (the column direction in this example) defined as a Y direction. Each of blocks of the matrix EM defined in a grid pattern can hold one full-size (i.e. em-size) character (two half-size (i.e. en-size) characters). In other words, the matrix EM can contain elements each formed by one desired full-size character (two desired half-size characters). In the present example, it is assumed that the matrix EM can contain M (integer satisfying the relationship of M≧1) characters arranged in the X direction by L (integer satisfying the relationship of L≧2) characters arranged in the Y direction, i.e. M by L characters at the maximum as elements thereof.

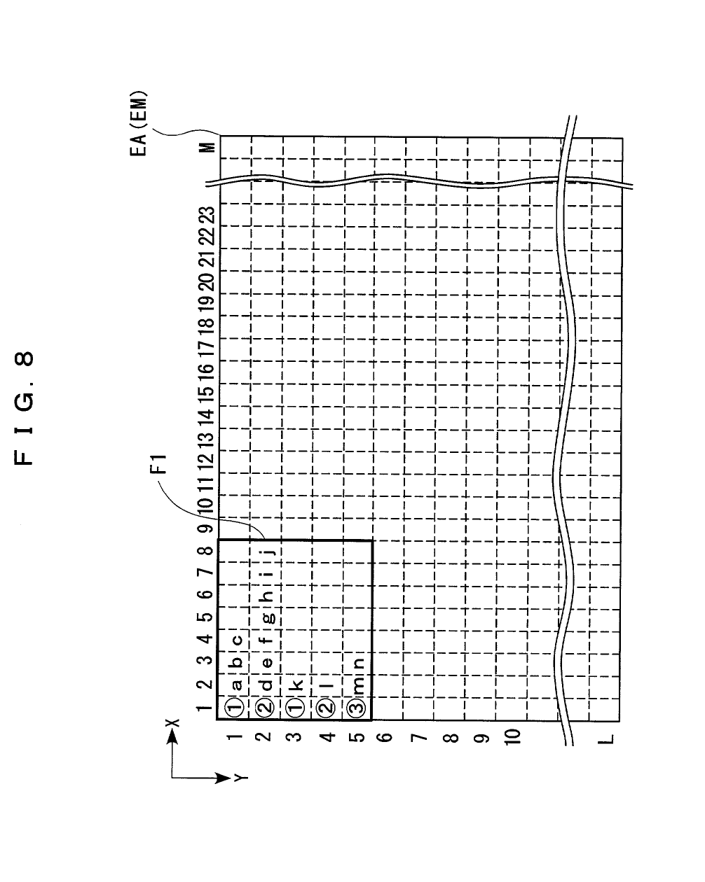

When the text (text 01) described with reference to FIG. 5A and shown in File 01 of FIG. 6 is selected for editing, an area EA storing text data to be edited (hereinafter referred to as “the text edit area”) corresponds to the above matrix (hereinafter referred to as “the text matrix”) EM, and text data (file data) F1 read (copied) into the text edit area EA forms an image conceptually (imaginarily) shown in FIG. 8.

Further, in the above case, an area (hereinafter referred to as “the text display area”) DA storing text data (as a display object) to be displayed on the edit screen (more specifically, the display screen 41 of the display 4) corresponds to a so-called partial matrix within the text edit area EA which can be represented by the image of the text matrix EM. More specifically, assuming that N (integer satisfying the relationship of 1≦N≦M) letters (characters) can be displayed in the X direction on the display screen 41, and J (integer satisfying the relationship of 1≦J≦L) letters (characters) can be displayed in the Y direction on the same, the text display area DA corresponds to a matrix (hereinafter referred to as “the display matrix”) which can contain elements of N by J characters at the maximum.

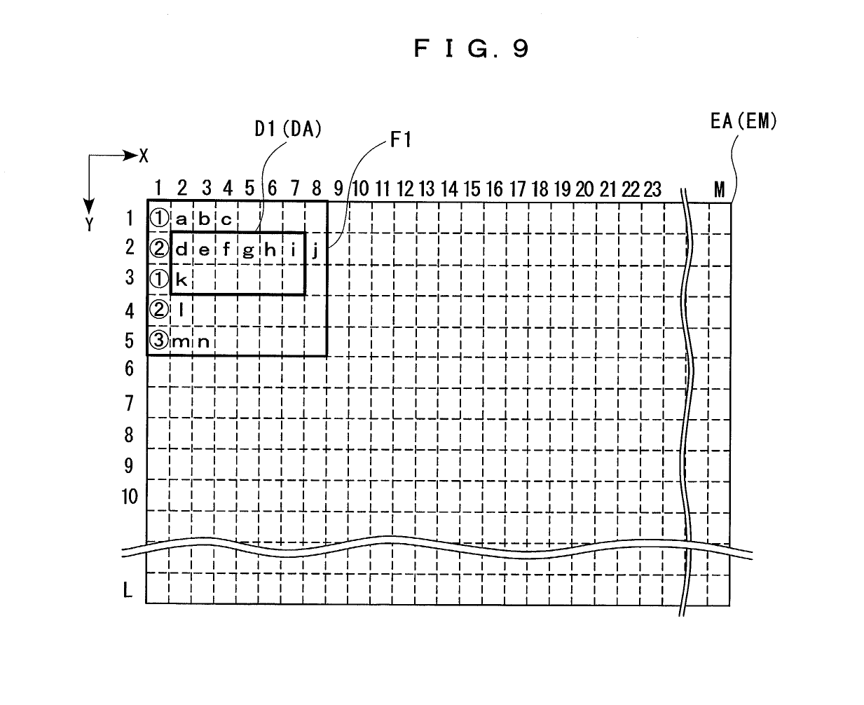

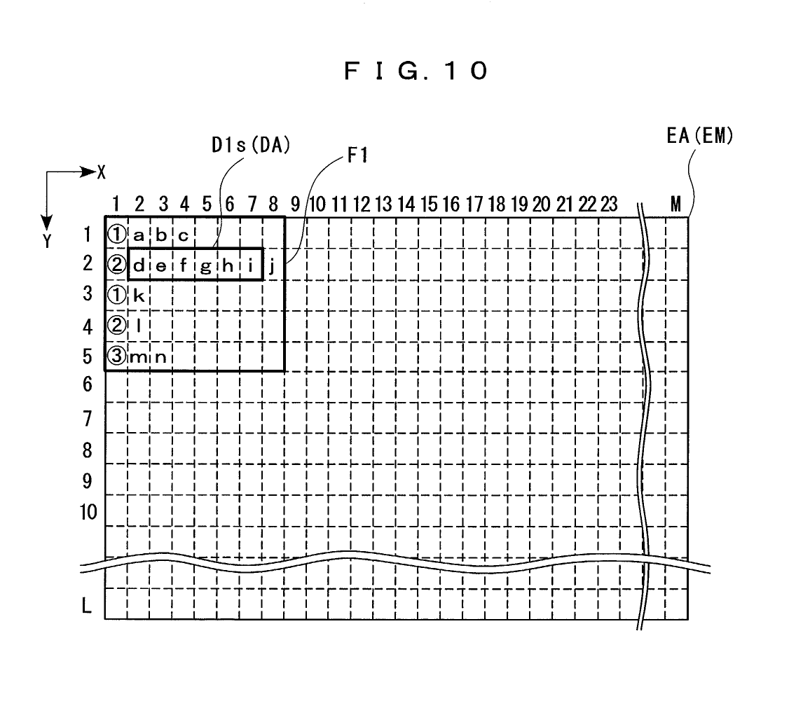

For instance, if the number of letters (characters) which can be displayed on the display screen 41 is equal to 6 (letters in the X direction, i.e. N=6) by 2 (lines in the Y direction, i.e. J=2), a text display area (corresponding to a display matrix) D1 is represented by an image as shown in FIG. 9. Further, if the number of letters (characters) which can be displayed on the display screen 41 is equal to 6 (letters in the X direction, i.e. N=6) by 1 (line in the Y direction, i.e. J=1), a text display area (corresponding to a display matrix) D1s is represented by an image as shown in FIG. 10.

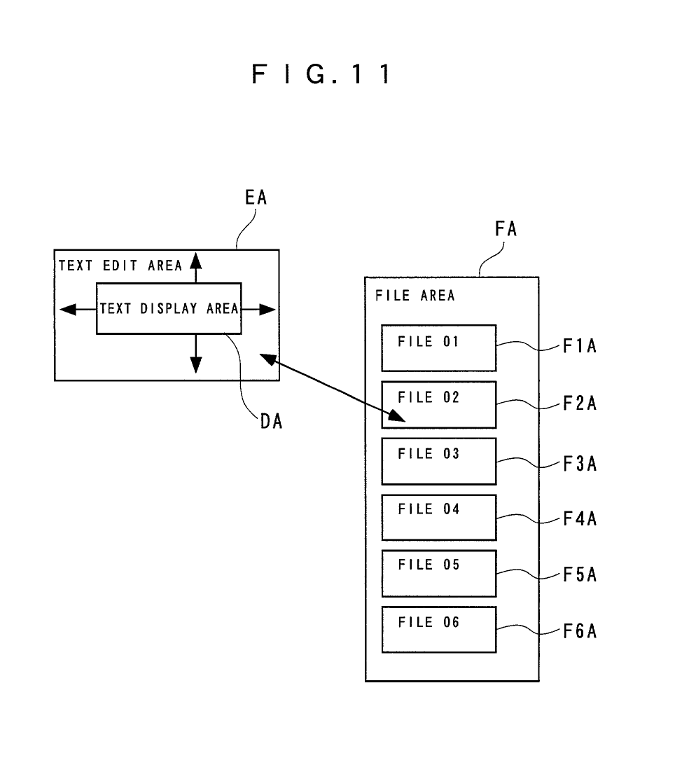

When contents of display are scrolled upward, downward, leftward or rightward on the display screen 41, i.e. in the text display area DA, according to a scroll instruction e.g. by the cursor keys, the text display area DA is shifted within the text edit area EA, as shown in FIG. 11, and hence the displayed image is changed. However, this change is possible exclusively within an identical text. In short, according to the conventional method, no text other than a single text currently displayed on the edit screen can be edited in response to input e.g. via the keyboard 3. Similarly, no text other than the text currently displayed on the edit screen can be printed in response to a print instruction given by depressing the print key.

For this reason, for editing and/or printing another text, it is required to read out the text from a file and display the same. For instance, in order to edit or print a text (text 02) in File 02 after editing or printing the text 01 in File 01, it is required to read (copy or loaded) a text data (file data) F2 of the text 02 into the text edit area from an area F2A storing the File 02, within a file area FA.

Further, during an edit operation for modifying a text currently displayed on the display screen, if the user wants to process another text, he is required to re-register (save) the currently displayed text in a file temporarily and then read out and display the another text. For instance, in the above example, before loading (reading out) the text data F2 of the text 02, it is required to write (save) the text data F1 of the text 01 currently edited, e.g. in an area F1A in which the File 01 was originally stored. In short, the conventional method necessitates frequent reading/writing of texts for carrying out various processes, including edit and printing operations.

Recent operating systems (OS's), such as those operating on personal computers, are capable of performing simultaneous display (multi-window display) of a plurality of edit screens corresponding respectively to texts different from each other. However, this method is applicable only to an apparatus, such as a personal computer, having a large-sized display screen, but not suitable for an apparatus, such as the tape printing apparatus 1 of the present embodiment, having a relatively small-sized display screen 41.

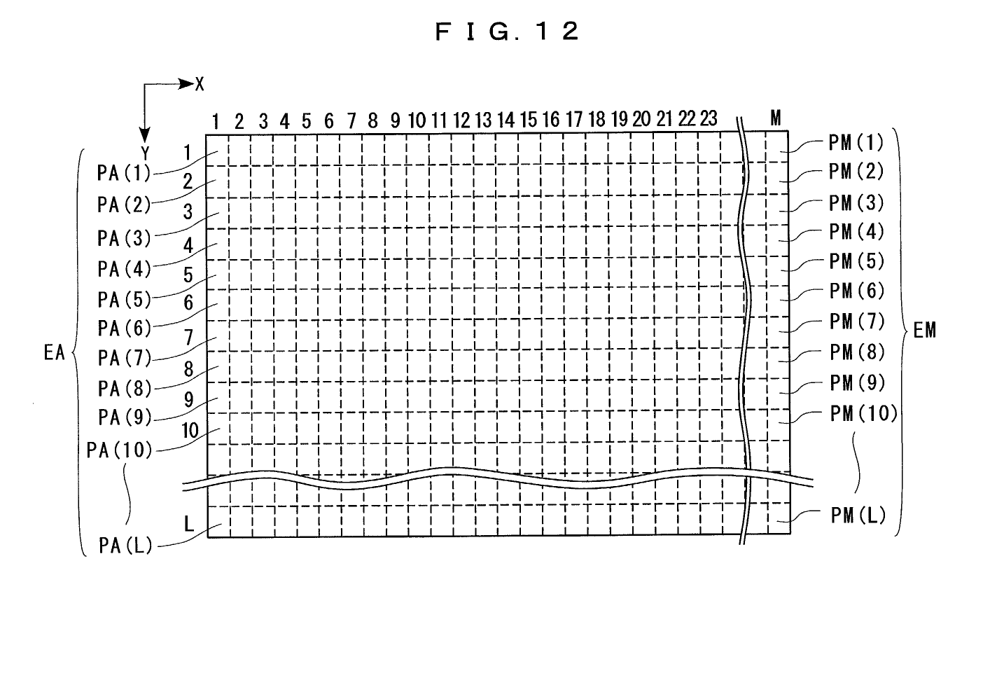

To solve the above problem, according to the tape printing apparatus 1, a matrix (k-th candidate processing matrix) PM(k) which is a k-th (k=1, 2, 3, . . . , L) one of partial matrices of the text matrix EM arranged in the Y direction and can contain elements of M characters at the maximum in the X direction is considered. In this case, in the same manner that the text edit area EA can be represented by the image of the text matrix EM, an area (hereinafter referred to as “the k-th candidate processing area”) PA(k) storing a text data TD(k) of a text (k-th text) as a processing candidate with a text number k can be represented by an image as shown in FIG. 12.

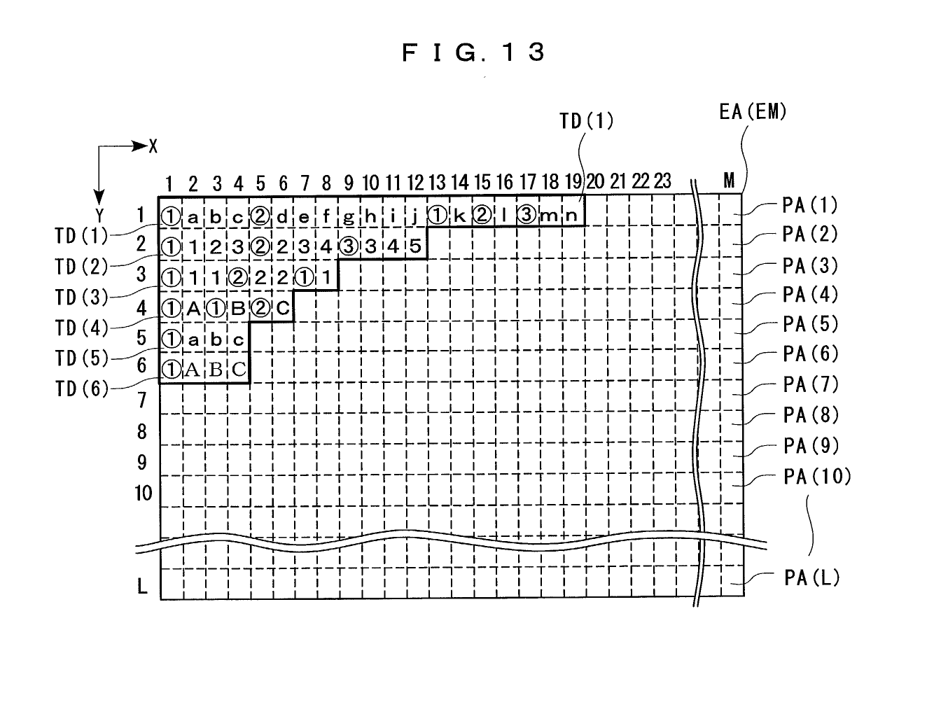

For instance, assuming that the texts 01 to 06 described hereinbefore with reference to FIGS. 5A to 5F and 6 are the first to sixth texts and their text data items are first to sixth text data TD(1) to TD(6), as shown in FIG. 13, these data items can be held (stored) in first to sixth candidate processing areas PA(1) to PA(6), respectively.

Further, by selecting one of the L candidate processing matrices ranging from the first candidate processing matrix PM(1) to the L-th candidate processing matrix PM(L) in FIG. 12 as a processing matrix PM(0), it is possible to designate text data TD(0) of the processing matrix PM(0) as a processing object. In other words, by selecting one of the first to L-th candidate processing areas PA(1) to PA(L), it is possible to select a corresponding one of the text data TD(1) to TD(L) stored in the respective first to L-th candidate processing areas PA(1) to PA(L) as text data TD(0) to be processed. In short, it is possible to execute processes including editing and printing on a plurality of texts as desired, without reading or writing the texts frequently.

For example, if the first candidate processing area PA(1) (i.e. the first candidate processing matrix PM(1)) is selected in FIG. 13, it is possible to edit the text data TD(1) and/or print the aforementioned print image G1 (see FIG. 5A) . Similarly, if the second candidate processing area PA(2) (i.e. the second candidate processing matrix PM(2)) is selected, it is possible to edit and/or print the text data TD(2) (see FIG. 5B). Further, if any one of the third to sixth candidate processing areas PA(3) to PA(6) is selected, it is possible to edit and/or print a corresponding one of the text data TD(3) to TD(6) (see FIGS. 5C to 5F).

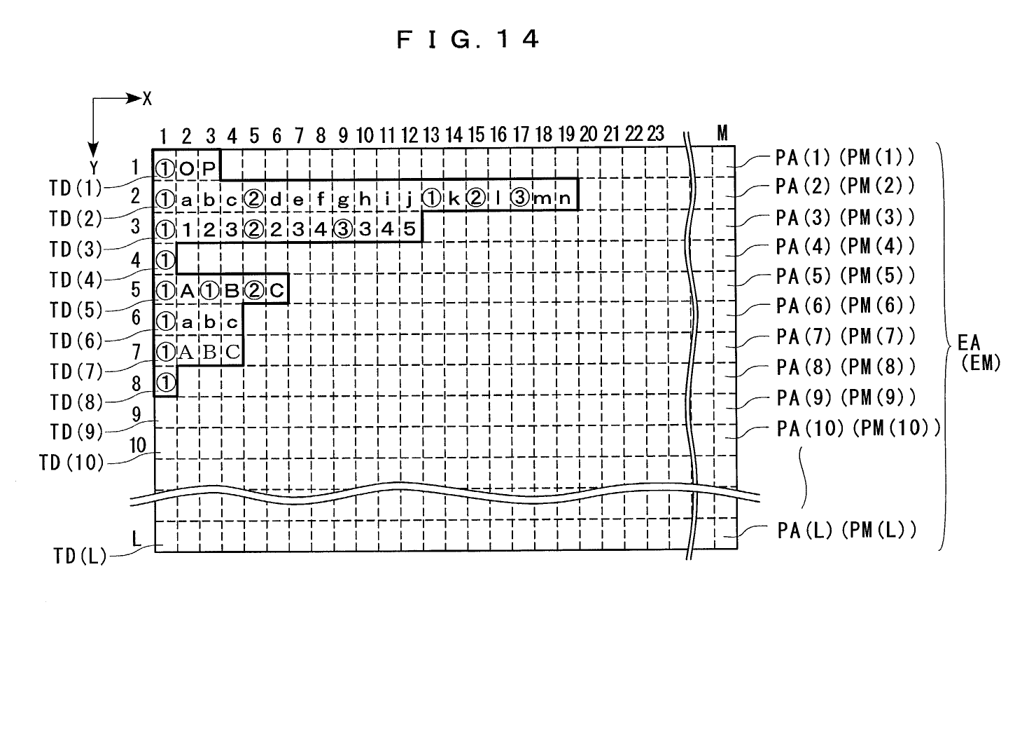

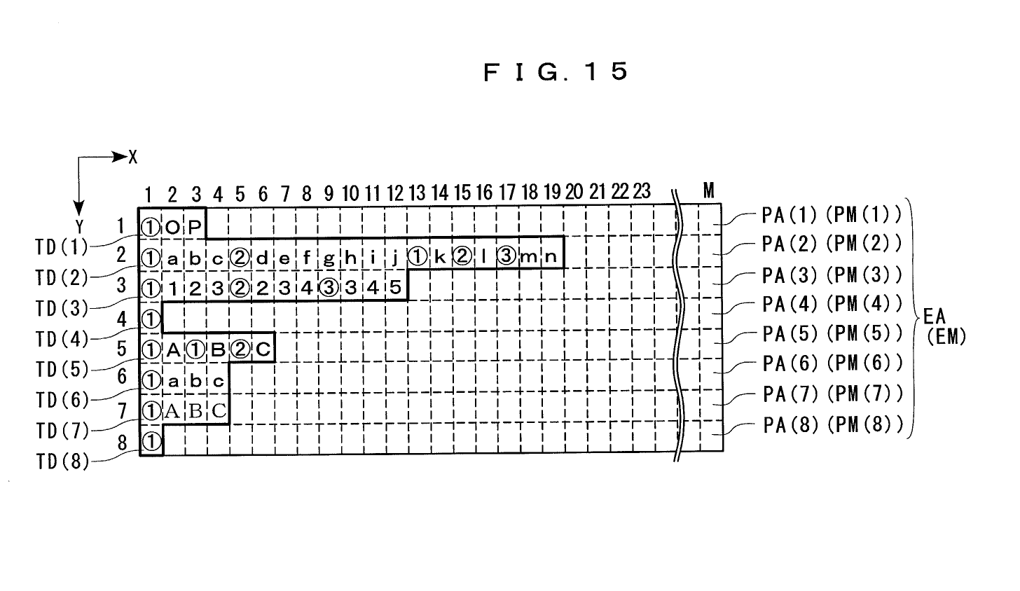

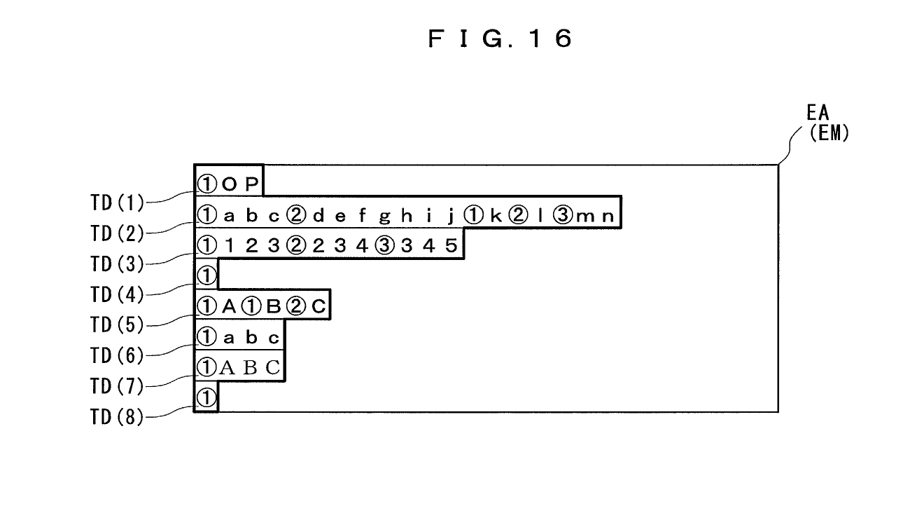

Although in FIG. 13, the first to sixth candidate processing areas PA(1) to PA(6) arranged sequentially in the Y direction are used for processing, this is not limitative, but discrete areas with blank areas interposed therebetween may be used. Further, as shown in FIG. 14, circled number 1 indicative of the line number for the first line of the first paragraph of a text may be stored in each of areas containing no text data, in advance. Furthermore, although in the above examples, the number of the elements of the text matrix EM in the Y direction is set to L, the number may be set to a convenient number by taking memory capacity or the like into consideration, and increased by a required number as occasion demands (the same goes for the number M of the elements in the X direction). In the following, L is assumed to be equal to eight, as shown in FIG. 15, for simplicity of description. Further, lines (dotted line) separating elements from each other are omitted, as shown in FIG. 16, so as to make figures easier to view.

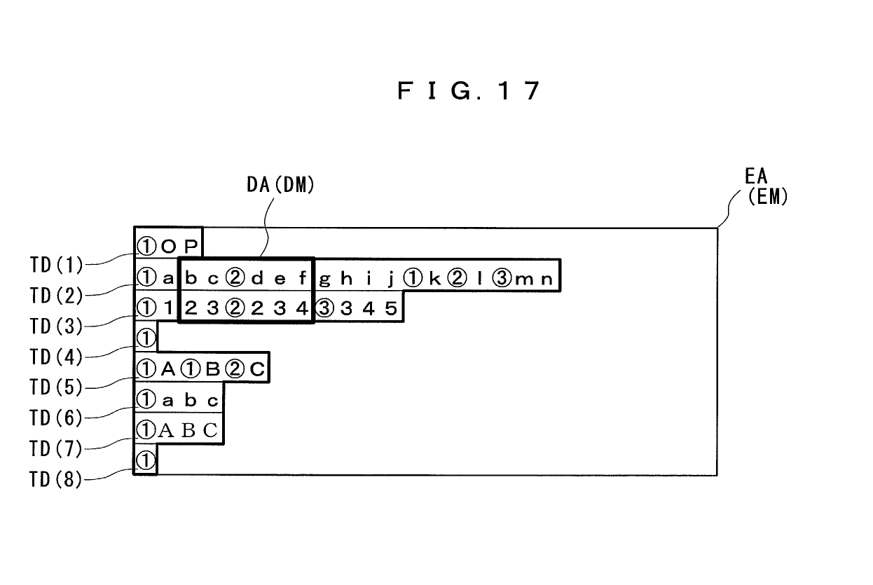

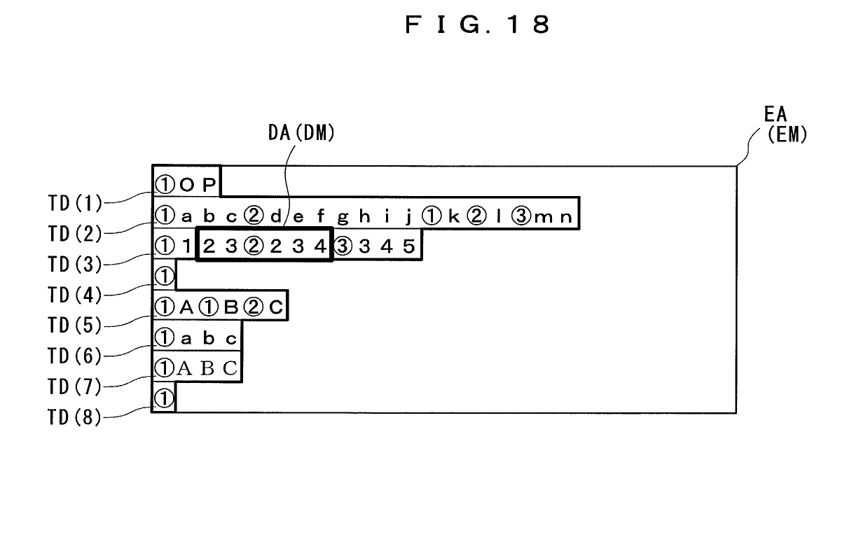

In the above character processing (text management), the relationship between the text matrix EM and the display matrix DM is similar to that in the prior art. However, since the text matrix EM has different elements from those in the prior art, contents for display are quite different. For instance, assuming that the number of letters (characters) which can be displayed on the display screen 41 is equal to 6 (letters in the X direction, i.e. N=6) by 2 (lines in the Y direction, i.e. J=2), the text display area DA (corresponding to the display matrix DM) is represented by an image shown in FIG. 17. Further, assuming that the number of letters (characters) which can be displayed on the display screen 41 is equal to 6 (letters in the X direction, i.e. N=6) by 1 (line in the Y direction, i.e. J=1), the text display area DA (corresponding to the display matrix DM) is represented by an image shown in FIG. 18.

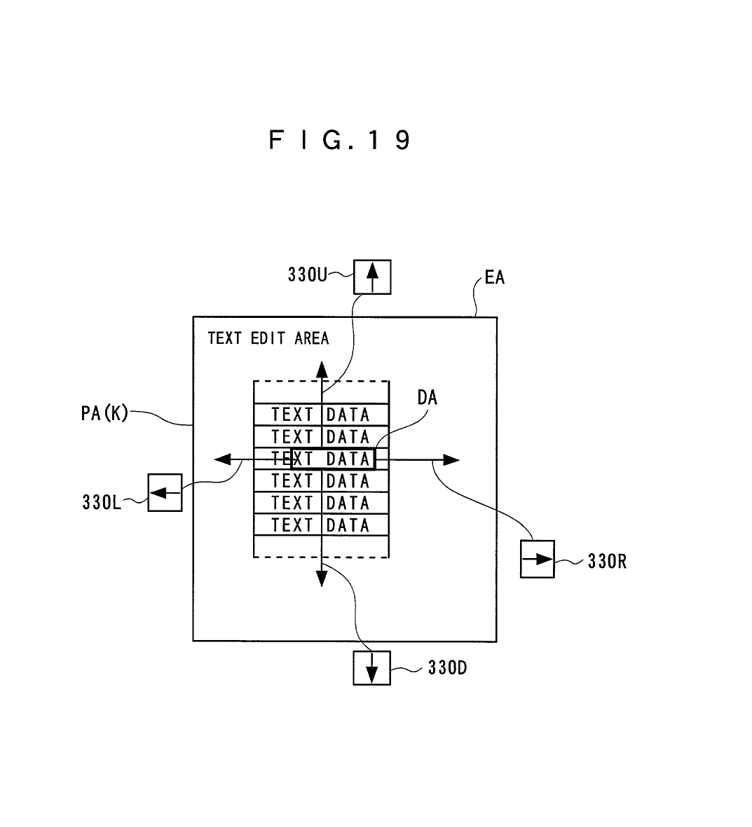

Further, in the tape printing apparatus 1, it is possible to change (scroll) the position of the text display area DA (display matrix DM) within the text edit area EA (text matrix EM) as shown in FIG. 19 by depressing the four cursor keys 330 (330U, 330D, 330L, 330R), and hence the user can cause each portion of the text edit area EA (text matrix EM) to be displayed for confirmation of stored text data. Also, in an edit process or the like, the user can view and check the result of the process (editing).

In the above case, scroll by the left or right arrow cursor key 330L or 330R, i.e. leftward or rightward scroll changes a displayed portion (display range) of an identical text just as in the prior art, whereas scroll by the up or down arrow cursor key 330U or 330D, i.e. upward or downward scroll causes other text data to be displayed.

Accordingly, when the text display area DA (display matrix DM) is limited to a single line as shown e.g. in FIG. 18, by configuring in advance such that currently displayed text data (the text data TD(3) in the figure) is set to text data TD(0) to be processed, the text data TD(0) to be processed can be selected by operating the cursor key 330 (330U or 330D in the present case). For instance, by depressing the print key in the state shown in FIG. 18, it is possible to select the text data TD(3) in the third candidate processing area PA(3) (corresponding to the third candidate processing matrix PM(3)) as text data TD(0) to be processed (processing object area PA(0) (corresponding to a processing matrix PM(0)), to thereby print the print image G2 shown in FIG. 5B.

This method can be applied not only to the above case of one-line display but also to a case of multiline display. For instance, when the text display area DA (display matrix DM) contains two lines as in the case of the example described above with reference to FIG. 17, by configuring such that the upper one (first one from the above) of the two (J=2) text data items (text data TD(2), TD(3) in the FIG. 17 example) is set to text data TD(0) to be processed, the text data TD(0) (=text data TD(2) in the FIG. 17 example) can be selected by operating the cursor key 330U or 330D. Thus, for example, by depressing the print key in the state shown in FIG. 17, the text data TD(2) can be selected as the text data TD(0) to be printed, whereby the FIG. 5A print image G1 is printed.

As is apparent from the above description, if it is configured such that the lower one (second one from the above) of the two (J=2) text data items is set to text data to be processed, it is possible to select the text data TD(3) as the text data TD(0) to be processed, similarly to the example described above with reference to FIG. 18, to thereby print the FIG. 5B print image G2.

In the examples described above with reference to FIGS. 17 to 19, since a processing object (processing object area PA(0) (corresponding to a processing matrix PM(0)) is selected from the J (two in FIG. 17 and one in FIG. 18) candidate processing matrices out of the eight (L=8) candidate processing areas PA(1) to PA(8) (corresponding to the candidate processing matrices PM(1) to PM(8)), each of which has at least a portion thereof overlapping the text display area DA (corresponding to the display matrix DM), it is possible to select the processing matrix as a processing object after viewing and recognizing at least the portion of the same displayed on the display screen. Further, since processed data is also displayed, it is easy to confirm or check the result of editing or the like.

Moreover, according to the tape printing apparatus 1, one candidate processing matrix in a predetermined position in sequence (the first or second one in FIG. 17 and the first one in FIG. 18) of J candidate processing matrices is designated as a processing object (processing object area PA(0) (corresponding to a processing matrix PM(0)). This means that even when display of J candidate processing matrices changes with a shift of the position of the text display area DA (corresponding to the display matrix DM), a candidate processing matrix which can be selected as a processing object is always in the predetermined position in sequence of J candidate processing matrices, and hence the processing object is automatically set by shifting the position of the text display area DA. In other words, it is possible to select a processing matrix by shifting the position of the text display area DA.

As described above, according to the character processing method employed in the tape printing apparatus 1, first, assuming that M is an integer satisfying the relationship of M≧1, L an integer satisfying the relationship of L≧2, N an integer satisfying the relationship of 1≦N≦M, and J an integer satisfying the relationship of 1≦J≦L, and that k is an arbitrary number indicative of a position in sequence and satisfying the relationship of 1≦k≦L, as described hereinbefore with reference to FIG. 7, the text matrix EM having M (in the X direction) by L (in the Y direction) desired (text) characters at the maximum as elements thereof and the corresponding text edit area EA (see FIGS. 7, 12), the display matrix DM having N (in the X direction) by J (in the Y direction) (display object) characters at the maximum as elements thereof and the corresponding text display area DA (see FIGS. 17 to 20), and the k-th (k=1 to L) candidate processing matrix PM having M (in the X direction) by 1 (in the Y direction) (k-th processing candidate) characters at the maximum as elements thereof and the corresponding k-th candidate processing area PA(k) (see FIGS. 12 to 15) are set as matrices and areas corresponding thereto, respectively.

Then, in the character processing method, text data representative of characters in the text matrix are stored in the text edit area EA in a manner correlated with the text matrix EM, and based on text data of characters in the display matrix among the characters in the text matrix, images of the characters in the display matrix are displayed. Further, one of the L candidate processing matrices ranging from the first candidate processing matrix PM(1) to the L-th candidate processing matrix PM(L) is selected as a processing matrix PM(0), and then each character contained in the processing matrix PM(0) is determined as a processing character, i.e. a character to be processed.

In short, by assigning character groups (e.g. documents (texts)) different from each other to the respective L candidate processing matrices ranging from the first candidate processing matrix PM(1) to the L-th candidate processing matrix PM(L), it is possible to select one of the L candidate processing matrices as a processing matrix PM(0) and determine or settle a character group (e.g. a text) within the processing matrix as a processing object, i.e. an object data to be processed.

In this case, as described hereinabove with reference to FIGS. 13 to 15, not character groups having characters arranged at random but character groups which each can form a document (text) (i.e. a k-th text described above) are arranged in the X direction in the text edit area EA (text matrix EM), or more specifically, arranged in (or assigned to) the respective L candidate processing areas PA(k) from the first candidate processing area to the L-th candidate processing area. This makes it possible to select one of the candidate processing areas PA(k) as a processing object (processing object area PA(0) (processing matrix PM(0)) and then finally determine a text within the processing matrix, as the processing object.

Accordingly, when any one of a plurality of documents (texts) is required to be selected as a processing object to be subjected to various processes including editing and printing, the present character processing method makes it possible to select the text for processing without carrying out any special operations for reading/writing texts. Further, in this case, it is not required to display the plurality of texts simultaneously, and hence a large-sized display screen is not necessary. Thus, in this character processing method, by using the small-sized display screen 41, it is possible to carry out editing, printing and/or other processes on a plurality of texts as desired without reading/writing each text frequently.

It should be noted that the above processing object (processing object area PA(0) (processing matrix PM(0)) can be selected not only by the method described above with reference to FIGS. 17 to 19, but also e.g. by inputting the number k of a desired k-th processing candidate as a numerical value.

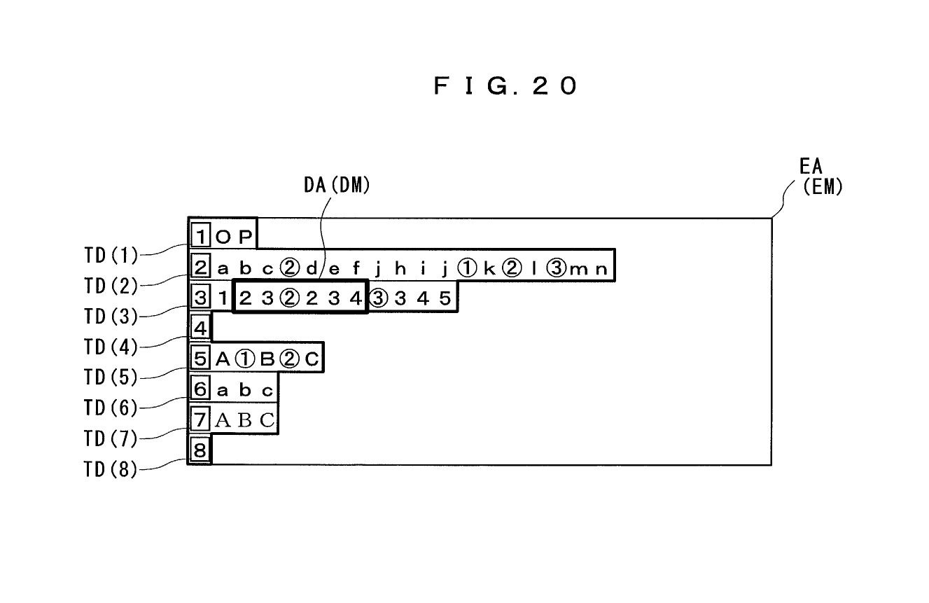

Further, although in the above examples, the circled numbers indicative of the respective line numbers are each added as an attribute character to the head of a corresponding one of the lines of each paragraph in a manner such that the circled number 1 corresponds to the first line, the circled number 2 corresponds to the second line, and so on, it is possible to further add a boxed number (i.e. a number enclosed by a box) indicative of a document (text) number to the head of each text, i.e. immediately before the first line of the first paragraph of each text. In this case, since each boxed number is placed immediately before a circled line number 1 added to the first line of the first paragraph of each text, the circled line number 1 can be omitted as shown in FIG. 20 corresponding to FIG. 18. Further, it is possible to add another kind of character as an attribute character indicative of a paragraph number in place of the circled number 1 placed immediately before the first line of each paragraph (the first line of each of the second paragraph et seq. in the case of a document number being used together).

In the above examples, the attribute characters hold attribute information of the respective character strings, and can be handled similarly to the other characters. Therefore, it is possible to display each character string together with an attribute character, which enables the user to readily grasp attribute information (including a document number, a paragraph number and a line number) of each character string. In particular, attribute characters of a document number, a paragraph number and a line number, contains information of the position of a character string, and hence it is easy for the user to obtain position information of a currently displayed character string, i.e. to recognize the positions of a document, a paragraph, and a line of the displayed character string in respective sequences of documents, paragraphs, and lines.

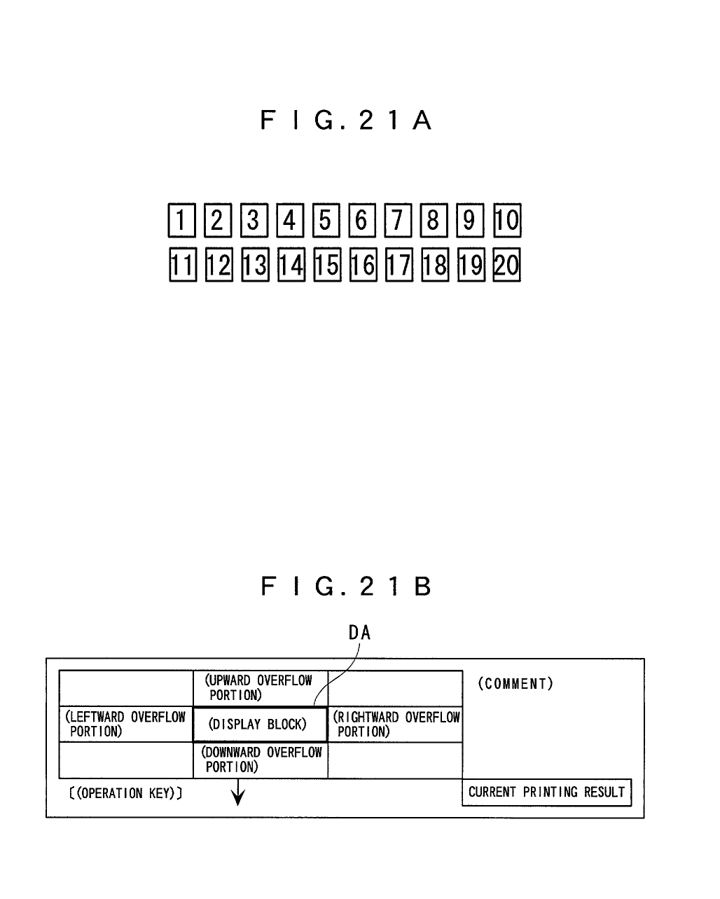

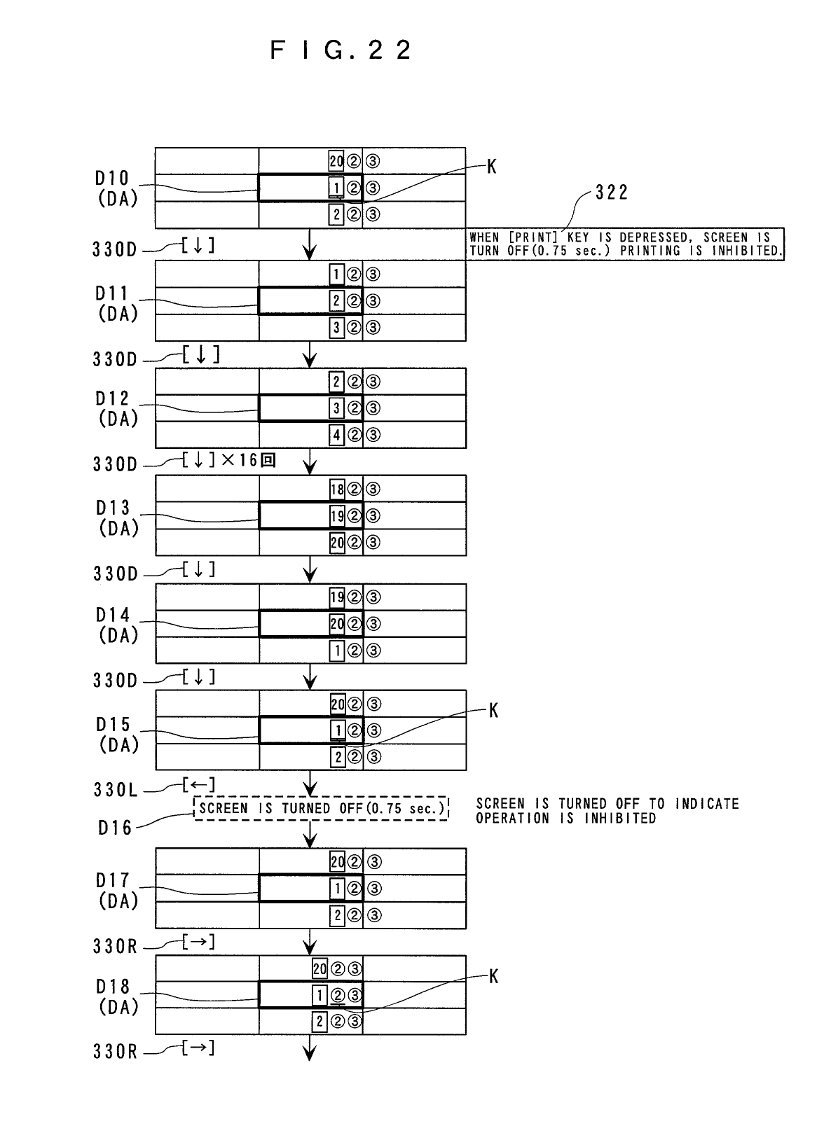

Next, description will be given of examples of an edit process and a printing process executed based on the character processing method according to the present embodiment. It is assumed in the following description that, as shown in FIG. 21, there are provided twenty documents (texts) to be handled, and that, as described above with reference to FIG. 20, a boxed number indicative of a document (text) number is added to each of the documents (texts) and the circled number 1 immediately before the first line of the first paragraph of each document (text) is omitted. Further, if a document (text) includes a plurality of paragraphs, the paragraphs can be handled similarly as described with reference to FIGS. 5A to 5F, and hence for simplicity of the description, it is assumed that each document (text) is formed by a single paragraph. For the same reason, each document (text) is assumed to contain three lines at the maximum, and the size of display portion (text display area DA corresponding to the display screen 41) is six characters in full size and one line. The cursor is assumed to be fixed at the position of the fifth displayed character and not shown unless required. FIG. 21B explains schematic representations of portions of each image shown in FIGS. 22 to 26. In the figure, portions corresponding to “xxx overflow portion” are only shown to help understanding but are not actually displayed. Characters further outward of each overflow portion are not shown. The box “current printing result” shows a print image according to settings of printing conditions of “uniform line size” and “centering”, but inter-linear spacing, margins, tape length, etc. are not reflected sufficiently in display of the image. Illustration of operations for switching between text entry modes between upper-case alphanumerical input, lower-case alphanumerical input, numerical input, etc. is omitted.

FIG. 22 et seq. are diagrams made based on a display format shown in FIG. 21B. Further, contents displayed on the display screen 41 of the display 4 corresponding to the text display screen DA are referred to as “screen Dxx” (x represents a digit) and reference numeral for such a particular screen is shown only by Dxx). Furthermore, for convenience of description, it is assumed that in an initial state, the document number (also serving as circled number 1 at the first line of the first paragraph) and line numbers 2, 3 (circled numbers 2, 3) of each of the documents having document number 1 (indicative of a first text) to document number 20 (indicative of a twentieth text) have already been registered (stored). Needless to say, a method may be employed in which documents (texts) can be increased in number as desired, and e.g. when a new document number is entered for the first time, candidate processing areas (candidate processing matrices) therefor are provided. However, in the present embodiment, the areas (first to twentieth candidate processing areas PA(1) to PA(20)) and attribute characters for the respective first to twentieth texts have already been provided.

Let it be assumed that an initial state of the first text is displayed as shown in FIG. 22 (D10) e.g. in the step of displaying the initial screen described hereinbefore with reference to FIG. 4. In this initial state, no character is provided for printing, so that if the print key 322 is depressed, the screen is turned off temporarily (e.g. 0.75 sec.) so as to indicate the fact (erroneous instruction), and then the initial state of the first text is displayed again. Further, when the down arrow cursor key 330D is depressed by the user in this state (D10), an initial state of the second text, for instance, is displayed (D11). Similarly, following the above, whenever the down arrow cursor key 330D is depressed, contents of the respective third to twentieth texts are sequentially displayed (D12 to D14).

This means that by successive depressions of the down arrow cursor key 330D (display is scrolled), the display state (screen) is successively changed from a state of text data TD(1) of the first candidate processing matrix PM(1) stored in the first candidate processing area PA(1) being selected as text data TD(0) (processing object area PA(0) (processing object PM(0)) from the whole text data of characters as elements of a text matrix EM stored in a text edit area EA to a state of text data TD(20) of the twentieth candidate processing matrix PM(20) stored in the twentieth candidate processing area PA(20) being selected as the text data TD(0). In short, by operating the cursor, it is possible to easily select and determine one of the twenty (L=20) candidate processing text data items TD(1) to TD(20) of the respective first to twentieth texts as the text data TD(0).

It should be noted that in the present example, display of the twentieth text is followed by display of the first text (i.e. the texts are displayed circularly or in rotation), so that if the down arrow cursor key 330D is further depressed in the state (D14) of the initial state of the twentieth text being displayed, the initial state of the first text is displayed (D15: the same as D10) . If the left arrow cursor key 330L is depressed in this state (D15), i.e. in a state (not only D15 but also D10 to D14) in which the cursor K is positioned on a text number and there is nothing (no character) in a space leftward of the text number, the screen is turned off temporarily (D16) so as to indicate the fact (erroneous instruction), and then the screen is restored to the previous state (D17).

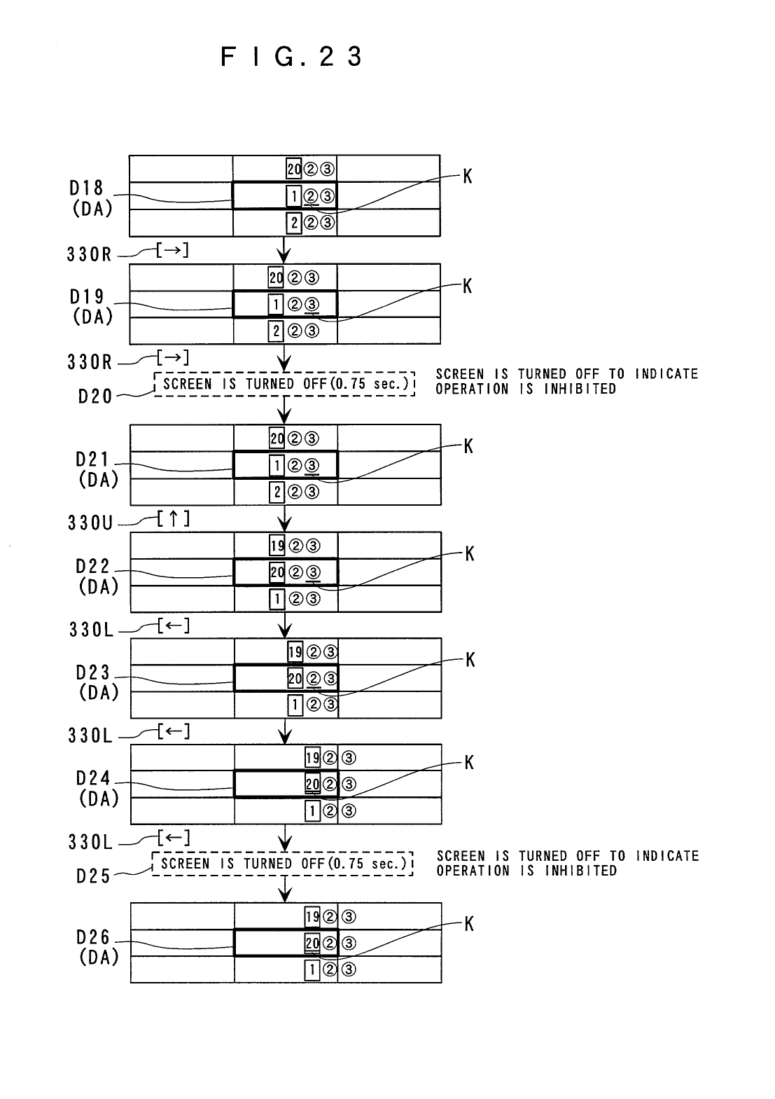

When the right arrow cursor key 330R is depressed in this state (D17: the same as D10 and D15), the cursor K relatively moves rightward (actually, since the cursor is in a fixed position, display of characters moves leftward) to a position below line number 2 indicative of the second line of the first text (D18 in FIGS. 22 and 23). Similarly, when the right arrow cursor key 330R is depressed in this state (D18) as shown in FIG. 23, the cursor K moves to a position below line number 3 indicative of the third line of the first text (D19) . If the right arrow cursor key 330R is further depressed in this state (D19), i.e. in a state in which there is no character in a space rightward of the line number, the screen is turned off temporarily (D20) so as to indicate the fact (erroneous instruction), and then the screen is restored to the previous state (D21).

Further, when the up arrow cursor key 330U is depressed in this state (D21: the same as D19), the initial state of the twentieth text is displayed (D22). When the left arrow cursor key 330L is depressed in this state (D22), i.e. in a state of the cursor K being positioned below line number 3 indicative of the third line of the twentieth text, the cursor K relatively moves leftward (display of characters moves rightward) to a position below line number 2 indicative of the second line of the twentieth text (D23). Similarly, when the left arrow cursor key 330L is depressed in this state (D23), the cursor K moves to a position below the text number of the twentieth text (D24). If the left arrow cursor key 330R is further depressed in this state (D24) in which there is no character in a space leftward of the text number, the screen is turned off temporarily (D25) so as to indicate the fact (erroneous instruction), and then the screen is restored to the previous state (D26).

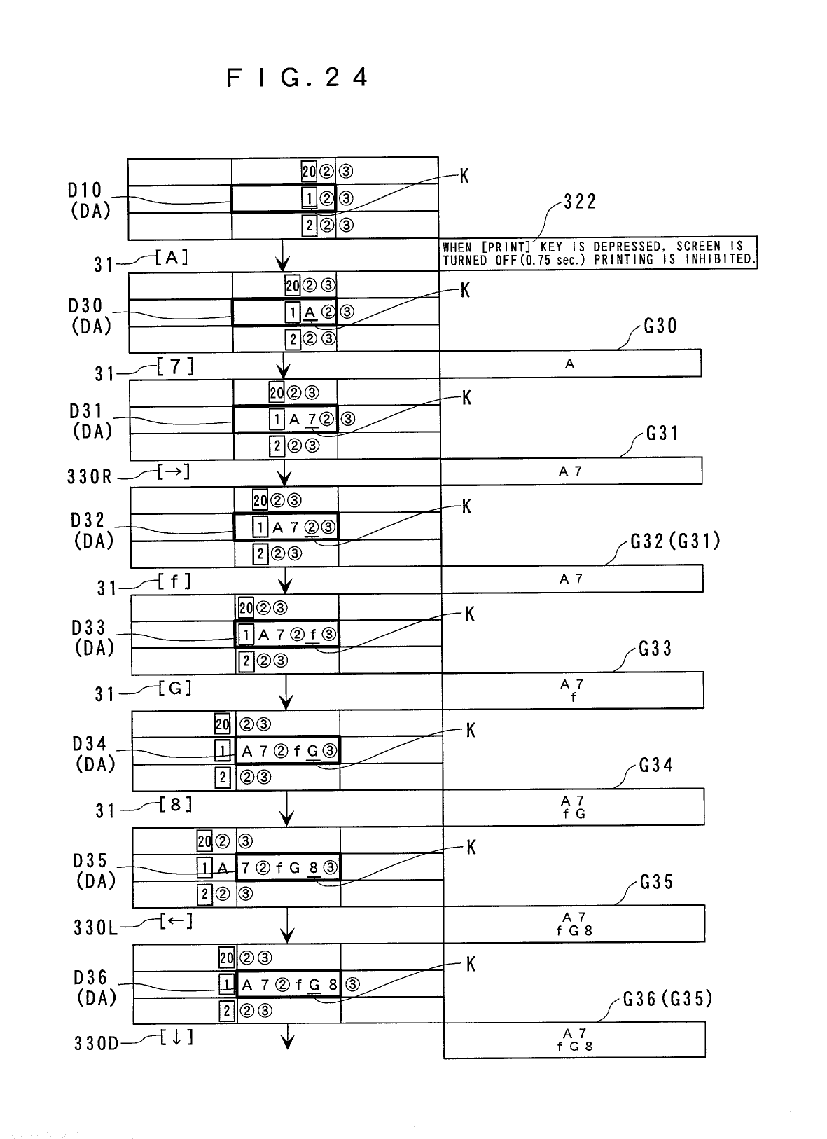

Then, as shown in FIG. 24, when “A” key 31 belonging to the alphabet key group included in the character key group 31 (hereinafter, keys of this kind are all designated by reference numeral 31 for the character key group) is depressed by the user in the state (D10 in FIGS. 22 and 24) described above with reference to FIG. 22, display of the characters (in this case, only the character “1” indicative of the text number of the twentieth text) above and leftward of the position of the cursor K (located below the character “1” in this case) is shifted leftward, and a character “A” entered by operation of the “A” key is inserted into a space above the position of the cursor K (D30). Within the text edit area EA (text matrix EM), code data indicative of the character “A” is inserted in a position (rightward of the text number “1” and immediately before the line number 2) as part of the text data. Accordingly, when the print key 322 is depressed in this state (D30), a print image G30 of the single character “A” is printed.

Similarly, when a “7” key 31 is depressed in this state (D30), display of the characters leftward of the position of the cursor K (located below the character “A” in this case) is shifted leftward, and the character “7” entered by the operation of the “7” key is inserted into a space above the position of the cursor K (D31). Also, within the text edit area EA (text matrix EM), the character“7” is inserted, so that when the print key 322 is depressed in this state (D31), a print image G31 of 2 (characters) by 1 (line) characters “A7” is printed.

When the right arrow cursor key 330R is depressed in this state (D31), the cursor K relatively moves rightward to a position below the line number 2 indicative of the second line of the first text (D32). In this state (D32), the text data has not changed at all, so that when the print key 322 is depressed, a print image G32 of 2 (characters)×1 (line) characters “A7”, which is identical to the print image G31, is printed.

When “f” key 31 is depressed in this state (D32), display of the characters above and leftward of the position of the cursor K (located below the circled number “2” indicative of the line number of the first text in this case) is shifted leftward, and the character “f” entered by the operation of the “f” key is inserted into a space above the position of the cursor K (D33). Also, within the text edit area EA (text matrix EM), the character “f” is inserted, so that when the print key 322 is depressed in this state (D33), a print image G33 having a first line formed by the two-character image “A7” and a second line formed by a one-character image “f” is printed.

Similarly, following the above state (D33), when a “G” key 31 and an “8” key 31 are sequentially depressed to shift display of the characters above and leftward of the position of the cursor K, characters “G” and “8” entered by the operation of the “G” key 31 and “8” key 31 are inserted into respective spaces above the position of the cursor K (D34, D35) . Since text data items corresponding to the respective characters “G” and “8” are also inserted, when the print key 322 is depressed in these states (D34, D35), a print image G34 having a first line formed by the two-character image “A7” and a second line formed by two-character image “fG” and a print image G35 having a first line formed by the two-character image “A7” and a second line formed by three-character image “fG8” are printed, respectively.

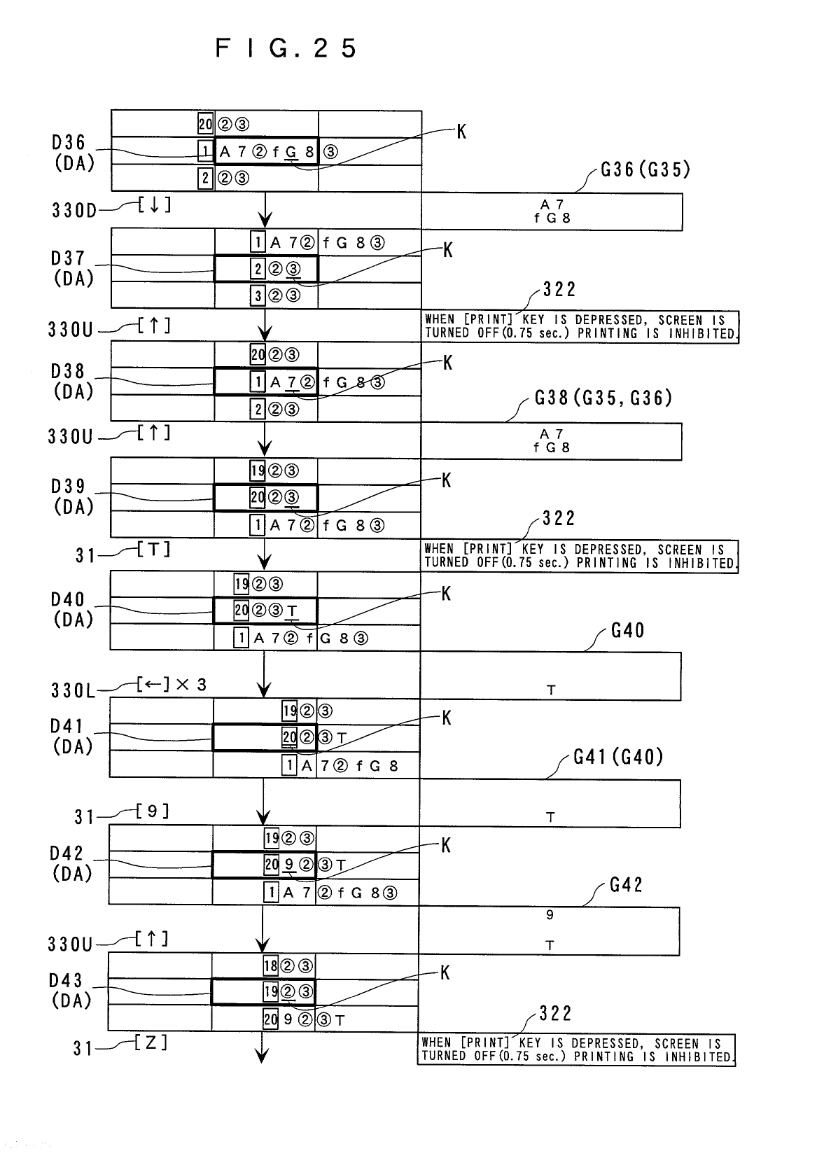

When the left arrow cursor key 330L is depressed in this state (D35), the cursor K relatively moves leftward to a location below the character “8” at the trailing end of the second line of the first text (D36 in FIGS. 24 and 25). In this state (D36), the text data has not changed at all, so that when the print key 322 is depressed, a print image G36 which is identical to the print image G35 is printed.

Then, when, as shown in FIG. 25, the down arrow cursor key 330D is depressed by the user in the state (D36 in FIGS. 24 and 25) described above with reference to FIG. 24, the screen changes from the state (D36) of the contents of the first text being partially displayed to a state (D37) of the initial state of the second text being displayed. In principle, at this time point, the cursor K should move to a position (below a sixth character of the second text) corresponding to the previous position of the cursor K (located below the character “G” which is the sixth character of the first text). In the present case, however, the second text has only three characters (i.e. the sixth character does not exist), and hence the cursor K moves to the trailing end of the second text (i.e. to a location below the third character of the second text) (D37) . If the print key 322 is depressed in this initial state (D37) in which there is no character for printing, the screen is turned off temporarily so as to indicate the fact (erroneous instruction), and then the screen is restored to the previous state (D37).

Further, when the up arrow cursor key 330U is depressed in the state (D37), the screen changes from the state (D37) of the contents of the second text being displayed to a state (D38) of the contents of the first text being partially displayed. In this case, the position of the cursor K is shifted to the position (below the character “7” which is the third character of the first text) corresponding to the previous cursor position (below the line number 3 which is the third character of the second text) (D38). When the print key 322 is depressed in this state (D38), a print image G38 identical e.g. to the aforementioned print image G35 corresponding to the first text is printed.

Further, when the up arrow cursor key 330U is depressed in the state (D38), the screen changes from the state (D38) of the contents of the first text being partially displayed to a state (D39) of the contents of the twentieth text being displayed. In this case, the position of the cursor K is shifted to the location below the line number 3 which is the third character of the twentieth text. If the print key 322 is depressed in this initialized state (D39) in which there is no character for printing, the screen is turned off temporarily so as to indicate the fact (erroneous instruction), and then the screen is restored to the previous state (D39).

When “T” key 31 is depressed in this state (D39), display of the characters above and leftward of the position of the cursor K (located below the line number 3 in this case) is shifted leftward, and a character “T” entered by the operation of the “T” key is inserted into a space above the position of the cursor K (D40). Also, within the text edit area EA (text matrix EM), the character “T” is inserted, so that when the print key 322 is depressed in this state (D40), a print image G40 having a third line formed by a one-character image “T” is printed.

When the left arrow cursor key 330L is depressed three times from this state (D40), the cursor K relatively moves leftward by a distance corresponding to three characters to a location below the text number “20” (D41). The text data has not changed at all, and hence when the print key 322 is depressed, a print image G41 identical to the print image 40 is printed.

When “9” key 31 is depressed in this state (D41), display of the character (text number 20 alone) above the cursor position (below the text number 20) is shifted leftward, and the character “9” entered by the operation of the “9” key is inserted into a space above the cursor position (D42). Also, within the text edit area EA (text matrix EM), the character “9” is inserted, so that when the print key 322 is depressed in this state (D42), a print image G42 having a first line formed by a one-character image “9” and a third line formed by a one-character image “T” is printed.

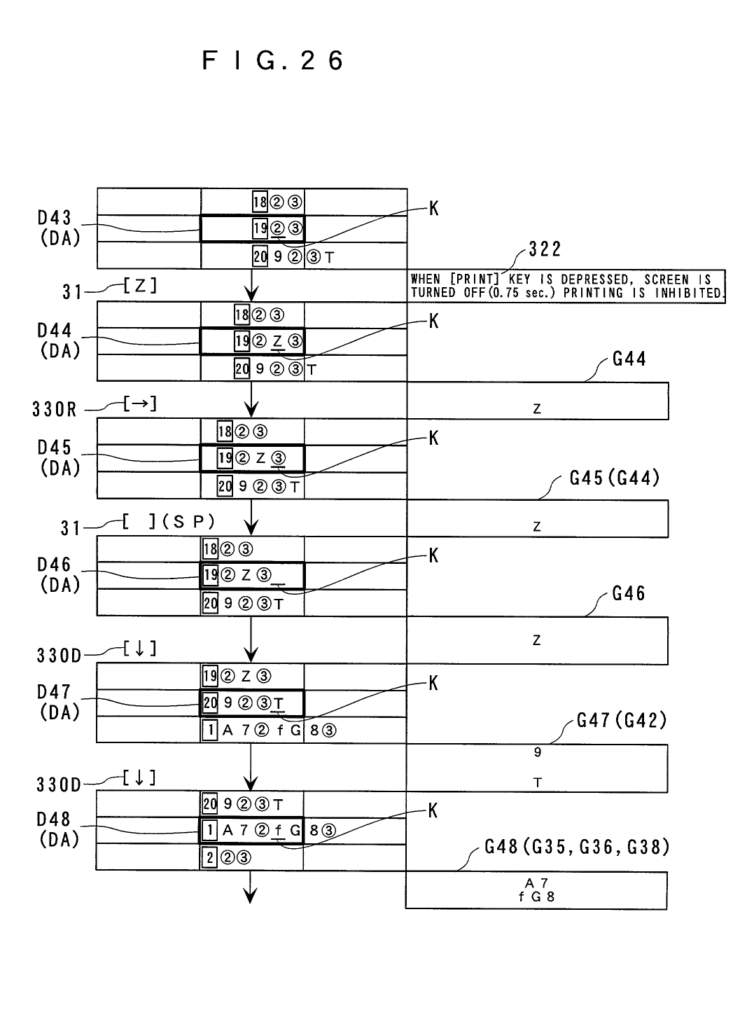

Further, when the up arrow cursor key 330U is depressed in the state (D42), the screen changes from the state (D42) of the contents of the twentieth text being partially displayed to a state (D43 in FIGS. 25 and 26) of the contents of the nineteenth text being displayed. In this case, the position of the cursor K is shifted to a location below line number 2 of the nineteenth text which corresponds in position to the second character of the twentieth text. If the print key 322 is depressed in this initialized state (D43) in which there is no character for printing, the screen is turned off temporarily so as to indicate the fact (erroneous instruction), and then the screen is restored to the previous state (D43).

Subsequently, as shown in FIG. 26, when “Z” key 31 is depressed in this state (D43 in FIGS. 25 and 26), display of the characters above and leftward of the cursor position (below the line number 2) is shifted leftward, and the character “Z” entered by the operation of the “Z” key is inserted into a space above the cursor position (D44). Also, within the text edit area EA (text matrix EM), the character “Z” is inserted, so that when the print key 322 is depressed in this state (D44), a print image G45 having a second line formed by a one-character image “Z” is printed.

When the right arrow cursor key 330R is depressed in this state (D44), the cursor K relatively moves rightward to a location below line number 3 of the nineteenth text (D45). The text data has not changed at all, and hence when the print key 322 is depressed, a print image G45 identical to the print image 44 is printed.

When space key 31 is depressed in this state (D45), display of the characters above and leftward of the cursor position (below the line number 3) is shifted leftward, and the space SP entered by the operation of the space key is inserted into a space above the cursor position (D46). Also, within the text edit area EA (text matrix EM), the space SP is inserted, so that when the print key 322 is depressed in this state (D46), a print image G46 having a second line formed by a one-character image “Z” and a third line formed by a one-character space image (i.e. an image of a space corresponding to one character) is printed.

Further, when the down arrow cursor key 330D is depressed in the state (D46), the screen changes from the state (D46) of the contents of the nineteenth text being displayed to a state (D47) of the contents of the twentieth text being displayed. In this case, the position of the cursor K is shifted to a location below the character “T” of the third line of the twentieth text, which corresponds in position to the fifth character of the nineteenth text. When the print key 322 is depressed in this state (D47), a print image G47 identical to the aforementioned print image G42 is printed.

Further, when the down arrow cursor key 330D is depressed in the state (D47), the screen changes from the state (D47) of the contents of the twentieth text being displayed to a state (D48) of the contents of the first text being partially displayed. In this case, the position of the cursor K is shifted to a location below the character “f” of the second line of the first text, which corresponds in position to the fifth character of the twentieth text. When the print key 322 is depressed in this state (D48), a print image G48 identical to the aforementioned print image G35 or the like is printed.

As described above, according to the character processing (or text managing) method employed in the tape printing apparatus 1 of the present invention, it is possible to set an edit object matrix as a processing object (processing object area PA(0) (processing matrix PM(0)) and then, add, delete or modify text data TD(0) of processing characters, to thereby edit characters in a text edit area EA (text matrix EM).

Further, according to the character processing method, it is possible to set a print medium matrix as a processing object (processing object area PA(0) (processing matrix PM(0)) and print at least a portion of an image of processing characters on a tape (print medium) T based on text data TD(0) of the characters. It should be noted that, as described hereinbefore, when processing characters include attribute characters, particularly ones indicative of a document (text) number, a paragraph number and a line number, the attribute characters are not printed, but character strings accompanied by the respective attribute characters can be printed (e.g. in a paragraph designated by the paragraph number or on a line designated by the line number) based on the attribute characters.

From another viewpoint, in the character processing (or text managing) method employed in the tape printing apparatus 1 according to the embodiment of the present invention, text data items TD(k) to be processed independently from each other are assigned to respective lines, and L (integer satisfying the relationship of L≧2) text data items TD(1) to TD(L) each of which can be a processing candidate are stored as L lines of text data items TD(1) to TD(L). Further, at least part of at least one of the L lines of text data items TD(1) to TD(L) is selected as a display object, and an image of text data within the display object (e.g. TD(2) and TD(3) in FIG. 17, TD(3) in FIGS. 18 and 20) is displayed.

Then, one text data item (e.g. TD(2) or TD(3) in FIG. 17, TD(3) in FIGS. 18 and 20), which was displayed at least partially, of the L candidate processing text data items TD(1) to TD(L) is selected as text data TD(0) to be processed. In this case, since the text data to be processed is displayed at least partially, the user can process the text data after having viewed and recognized the same by the display. In the examples shown in FIGS. 18 et seq., since only one line is displayed, text data of the displayed line (one line: one item) is necessarily selected as a processing object.

Further, in the text managing method, a text data item TD(0) for processing is text data of a predetermined position in a sequence of lines (the first or second line in FIG. 17 and the first line in each of in FIG. 18 et seq. in which a single line is displayed) for display. Therefore, when a line for display is determined, text data TD(0) to be processed is also determined. Conversely, by changing the line for processing, the processing object can be also changed.

In the tape printing apparatus 1, since the cursor K functions as selection means for selecting a processing object, it is possible to change or select a processing object readily by operating the cursor K. In the case of changing or selecting a processing object, since it is possible to change a displayed one of the L text data items TD(1) to TD(L), the user can confirm the stored text data by displaying portions of the respective L text data items TD(1) to TD(L). Particularly, since a displayed line (or one in a predetermined position in sequence of displayed lines) is selected as a processing object, a processing object can be changed by changing the displayed line by relatively moving the cursor K upward or downward by operating the up arrow cursor key 330U or the down arrow cursor key 330D.

In this case, it is possible to designate all the L text data items TD(1) to TD(L) as processing candidates simultaneously and then select a processing object without carrying out any special operation for reading/writing each text data. Further, since it is not required to display the plurality of text data items simultaneously, a large-sized display screen is not needed. Thus, even if a small-sized display screen is used, with a plurality of texts independent from each other being simultaneously designated as processing candidates, this text managing method makes it possible to carry out editing, printing and/or other processes on a displayed text as desired without reading/writing each text frequently.

Further, in the above examples described with reference to FIG. 22 et seq., display of the twentieth text is followed by display of the first text (i.e. the texts are displayed circularly or in rotation). In these cases, the lines to be displayed are changed in a circularly displayable manner such that a line which is immediately preceding and adjacent to the first line of L lines is an L-th line, and a line which is immediately following and adjacent to the L-th line is the first line. Therefore, it is possible to make average the time and labor required for each operation for changing a displayed line to another desired line, thereby carrying out the operation efficiently.

Although in the above embodiment, the tape printing apparatus is employed by way of example, this is not limitative, but the method and apparatus of the present invention can be applied to an apparatus of any other type which is capable of editing and printing character strings (or texts), such as a printing apparatus for printing an image of an edited character string (or text) on a print medium other than a tape, and more particularly to an apparatus which is capable of editing and printing a plurality of texts by using a small-sized display screen.

Further, the objects of the present invention can also be achieved by supplying a system or an apparatus including a computer with a storage medium storing software program modules for realizing the above embodiment. In this case, the program modules read from the storage medium achieve the novel functions of the present invention, and the storage medium storing the program modules constitutes the present invention.

In the above embodiments, the program modules are stored in the ROM 220 of the tape printing apparatus. However, when they are supplied via a storage medium, they are once stored in a storage medium section, not shown, of the tape printing apparatus, and read therefrom for execution. The storage medium for supplying the program modules may be a floppy disk, a hard disk, an optical memory disk, a magneto-optical disk, a CD-ROM, an MO, a CD-R, a DVD, a magnetic tape, a nonvolatile memory card, or the like. However, the storage medium is not limited to a specific one, and any medium which is capable of storing the above program modules can be employed.

It is further understood by those skilled in the art that the foregoing is a preferred embodiment of the invention, and that various changes and modifications may be made without departing from the spirit and scope thereof.

What is claimed is:

1. A method of processing characters, comprising the steps of:
setting, as a text matrix, a matrix which is capable of having elements of M by L characters which are arbitrary at the maximum, where M represents a number of characters which can be arranged in an X direction as one of a row direction and a column direction in said matrix and is defined as an integer equal to or larger than 1 and L represents a number of characters which can be arranged in a Y direction as another of said row direction and said column direction and is defined as an integer equal to or larger than 2;
storing text data representative of each character contained in said text matrix in a manner correlated with a position of said character in said text matrix;
setting, as a display matrix, a partial matrix corresponding to a portion of said text matrix and capable of having elements of N by J characters at the maximum, where N represents a number of characters which can be arranged in said X direction and is defined as an integer satisfying the relationship of 1≦N≦M and J represents a number of characters which can be arranged in said Y direction and is defined as an integer satisfying the relationship of 1≦J≦L;
displaying an image of each character contained in said display matrix in a manner correlated with a position of said character in said display matrix, based on said text data of said character;
setting, as a k-th candidate processing matrix, an arbitrary k-th one, where k=1, 2, 3, . . . or L, of L partial matrices of said text matrix arranged in said Y direction as first to L-th candidate processing matrices each of which is capable of having one character in said Y direction and M characters at the maximum in said X direction; and
selecting one of said L candidate processing matrices as a processing matrix, and then determining characters contained in said processing matrix as processing characters.

2. A method according to claim 1, further comprising the step of shifting a position of said display matrix in said text matrix.

3. A method according to claim 1, wherein said processing matrix is selected from J candidate processing matrices of said L candidate processing matrices, each of said J candidate processing matrices having at least part thereof overlapping said display matrix.

4. A method according to claim 3, wherein said processing matrix is in a predetermined position in sequence of said J candidate processing matrices.

5. A method according to claim 1, further comprising the step of editing said text data of said processing characters by addition, deletion or modification.

6. A method according to claim 1, wherein said characters in said text matrix include characters forming at least one character string,
said k-th candidate processing matrix has one or more character strings arranged in said X direction.

7. A method according to claim 6, wherein said characters in said text matrix include at least one attribute character accompanying said characters forming said at least one character string, said at least one attribute character indicating at least one of an attribute of each character string and an attribute of said characters forming said each character string.

8. A method according to claim 7, wherein said attribute character includes a position information character indicative of at least one of a line number, a paragraph number and a document number of said at least one character string.

9. A method according to claim 6, wherein the step of storing text data includes the step of storing format information of each character string to be laid out.

10. A method according to claim 1, further comprising the step of printing at least part of an image of said processing characters on a print medium, based on said text data of said processing characters.

11. A method according to claim 10, wherein said print medium is a tape.

12. A character processing apparatus for processing characters, comprising:
text matrix-setting means for setting, as a text matrix, a matrix which is capable of having elements of M by L characters which are arbitrary at the maximum, where M represents a number of characters which can be arranged in an X direction as one of a row direction and a column direction in said matrix and is defined as an integer equal to or larger than 1 and L represents a number of characters which can be arranged in a Y direction as another of said row direction and said column direction and is defined as an integer equal to or larger than 2;
text data-storing means for storing text data representative of each character contained in said text matrix in a manner correlated with a position of said character in said text matrix;
display matrix-setting means for setting, as a display matrix, a partial matrix corresponding to a portion of said text matrix and capable of having elements of N by J characters at the maximum, where N represents a number of characters which can be arranged in said X direction and is defined as an integer satisfying the relationship of 1≦N≦M and J represents a number of characters which can be arranged in said Y direction and is defined as an integer satisfying the relationship of 1≦J≦L;
display means for displaying an image of each character contained in said display matrix in a manner correlated with a position of said character in said display matrix, based on said text data of said character;
candidate processing matrix-setting means for setting, as a k-th candidate processing matrix, an arbitrary k-th one, where k=1, 2, 3, . . . or L, of L partial matrices of said text matrix arranged in said Y direction as first to L-th candidate processing matrices each of which is capable of having one character in said Y direction and M characters at the maximum in said X direction; and
processing object-selecting means for selecting one of said L candidate processing matrices as a processing matrix, and then determining characters contained in said processing matrix as processing characters.

13. A character processing apparatus according to claim 12, further comprising display matrix-shifting means for shifting a position of said display matrix in said text matrix.

14. A character processing apparatus according to claim 12, wherein said processing matrix is selected from J candidate processing matrices of said L candidate processing matrices, each of said J candidate processing matrices having at least part thereof overlapping said display matrix.

15. A character processing apparatus according to claim 14, wherein said processing matrix is in a predetermined position in sequence of said J candidate processing matrices.

16. A character processing apparatus according to claim 12, further comprising edit means for editing said text data of said processing characters by addition, deletion or modification.

17. A character processing apparatus according to claim 12, wherein said characters in said text matrix include characters forming at least one character string,
said k-th candidate processing matrix has one or more character strings arranged in said X direction.

18. A character processing apparatus according to claim 17, wherein said characters in said text matrix include at least one attribute character accompanying said characters forming said at least one character string, said at least one attribute character indicating at least one of an attribute of each character string and an attribute of said characters forming said each character string.

19. A character processing apparatus according to claim 18, wherein said attribute character includes a position information character indicative of at least one of a line number, a paragraph number and a document number of said at least one character string.

20. A character processing apparatus according to claim 17, wherein said text data-storing means includes means for storing format information of each character string to be laid out.

21. A character processing apparatus according to claim 12, further comprising printing means for printing at least part of an image of said processing characters on a print medium, based on said text data of said processing characters.

22. A character processing apparatus according to claim 21, wherein said print medium is a tape.

23. A computer-readable storage medium storing a program for causing a computer to execute a method of processing characters, the program comprising:
a module for setting, as a text matrix, a matrix which is capable of having elements of M by L characters which are arbitrary at the maximum, where M represents a number of characters which can be arranged in an X direction as one of a row direction and a column direction in said matrix and is defined as an integer equal to or larger than 1 and L represents a number of characters which can be arranged in a Y direction as another of said row direction and said column direction and is defined as an integer equal to or larger than 2;
a module for storing text data representative of each character contained in said text matrix in a manner correlated with a position of said character in said text matrix;
a module for setting, as a display matrix, a partial matrix corresponding to a portion of said text matrix and capable of having elements of N by J characters at the maximum, where N represents a number of characters which can be arranged in said X direction and is defined as an integer satisfying the relationship of 1≦N≦M and J represents a number of characters which can be arranged in said Y direction and is defined as an integer satisfying the relationship of 1≦J≦L;
a module for displaying an image of each character contained in said display matrix in a manner correlated with a position of said character in said display matrix, based on said text data of said character;
a module for setting, as a k-th candidate processing matrix, an arbitrary k-th one, where k=1, 2, 3, . . . or L, of L partial matrices of said text matrix arranged in said Y direction as first to L-th candidate processing matrices each of which is capable of having one character in said Y direction and M characters at the maximum in said X direction; and
a module for selecting one of said L candidate processing matrices as a processing matrix, and then determining characters contained in said processing matrix as processing characters.
